(19) United States
(12) Patent Application Publication
(10) Pub. No.: US 2013/0334402 A1
(43) Pub. Date: Dec. 19, 2013

(54) SOLID-STATE IMAGINGELEMENT, CALIBRATION METHOD OF SOLID-STATE IMAGINGELEMENT, SHUTTER DEVICE, AND ELECTRONIC APPARATUS

(71) Applicant: Sony Corporation, Tokyo (JP)

(72) Inventors: Kyoko Izuha, Kanagawa (JP); Koji Kadono, Kanagawa (JP); Kouichi Harada, Kanagawa (JP); Toshiyuki Kobayashi, Kanagawa (JP)

(21) Appl. No.: 13/909,881

(22) Filed: Jun. 4, 2013

(30) Foreign Application Priority Data
Jun. 14, 2012 (JP) 2012-134861
Mar. 11, 2013 (JP) 2013-048221

(51) Int. Cl. H01L 27/146; G02F 1/01

(52) U.S. Cl. CPC H01L 27/146; G02F 1/01; B82Y 20/00
USPC 250/208.1; 257/443; 359/238; 977/734

(57) ABSTRACT

Disclosed herein is a solid-state imaging element including: a plurality of pixels including a photoelectric conversion section; and a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film.

### BACKGROUND

The present technology relates to a solid-state imaging element including a nano-carbon laminated film, a calibration method of the solid-state imaging element, and an electronic apparatus using the solid-state imaging element. Further, the present technology relates to a shutter device including a nano-carbon laminated film and an electronic apparatus including the shutter device.

A solid-state imaging element typified by a CCD (Charge Coupled Device) image sensor and a CMOS (Complementary Metal Oxide Semiconductor) image sensor includes a photoelectric conversion section formed by a photodiode formed on the side of a light receiving surface of a substrate and a charge transfer section. In such a solid-state imaging element, the photodiode subjects light incident on the sensor section to photoelectric conversion to generate a signal charge. Then, the charge transfer section transfers the generated signal charge, and outputs the signal charge as a video signal. Such a device has a structure for subjecting light incident in a certain exposure time to photoelectric conversion, and accumulating a signal charge.

Japanese Patent Laid-Open No. 2006-190958 (hereinafter referred to as Patent Document 1) proposes a device that receives light in each wavelength region using a dielectric laminated film formed by laminating a plurality of dielectric layers having different indexes of refraction as an image sensor enabling imaging in a visible light region and an infrared region. As described in Patent Document 1, when wavelength selection is made by the dielectric laminated film, the infrared wavelength region that can be received is fixed due to the characteristics of the dielectric laminated film. Hence, the wavelengths of light that can pass through the dielectric laminated film cannot be modulated freely. Further, it is difficult to control variations in wavelength due to variations in film thickness of the dielectric laminated film, and there are large wavelength errors in regard to light incident obliquely with respect to a plane of incidence.

In addition, as described in Japanese Patent Laid-Open No. 2008-124941, indium tin oxide (ITO) has been principally used as an ordinary material for transparent electrodes in the past. In addition, Japanese Patent Laid-Open No. Hei 6-165003 and Japanese Patent Laid-Open No. 2005-102162 propose techniques that use a light control element such as an electrochromic layer or the like in a shutter device used in an electronic apparatus such as an imaging device or the like, and which change transmittance by applying a desired voltage to the electrochromic layer. Also in this case, ITO is used as transparent electrodes to apply the desired voltage to the electrochromic layer.

However, current ITO used as transparent electrodes has a low transmittance. Thus, when ITO is provided on the side of a light incidence surface of an image sensor, a decrease of about 10% in transmittance is caused per ITO film. Therefore, the use of transparent electrodes formed of ITO on the side of a light incidence surface of an image sensor decreases sensitivity. Further, because of a large film thickness of ITO, optical characteristics of ITO change.

### SUMMARY

In view of the above points, the present disclosure provides a solid-state imaging element that can perform imaging in ranges from a near-infrared region to a visible light region and which allows an amount of received light to be adjusted, a calibration method of the solid-state imaging element, and an electronic apparatus using the solid-state imaging element. The present disclosure also provides a shutter device whose light transmission characteristics are improved and an electronic apparatus using the shutter device.

A solid-state imaging element according to an embodiment of the present disclosure includes: a plurality of pixels including a photoelectric conversion section; and a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film.

In the solid-state imaging element according to the embodiment of the present disclosure, the transmittance of light and the wavelength region of transmissible light in the nano-carbon laminated film are changed by applying a desired voltage to the nano-carbon laminated film. This makes it possible to perform imaging in the ranges from the near-infrared region to the visible light region and allows an amount of light incident on the photoelectric conversion section to be adjusted.

A calibration method of a solid-state imaging element according to an embodiment of the present disclosure is a method of adjusting transmittance in a position corresponding to each pixel of the nano-carbon laminated film for each pixel in the above-described solid-state imaging element.

In the calibration method of the solid-state imaging element according to the embodiment of the present disclosure, the transmittance of the nano-carbon laminated film can be adjusted for each pixel. Thus, an amount of light incident on each pixel can be adjusted. A shutter device according to an embodiment of the present disclosure includes: a nano-carbon laminated film formed with a plurality of nano-carbon layers, transmittance of light and a wavelength region of transmissible light changing in the nano-carbon laminated film according to a voltage applied to the nano-carbon laminated film; and a voltage applying section applying the voltage to the nano-carbon laminated film. In the shutter device according to the embodiment of the present disclosure, the nano-carbon laminated film is formed with the plurality of nano-carbon layers. Therefore light transmission characteristics can be improved.

An electronic apparatus according to an embodiment of the present disclosure includes: the solid-state imaging element according to the above-described embodiment of the present disclosure; and a signal processing circuit for processing an output signal output from the solid-state imaging element. The nano-carbon laminated film is formed with the plurality of nano-carbon layers.

In the electronic apparatus according to the embodiment of the present disclosure, the transmittance of light and the wavelength region of transmissible light in the nano-carbon laminated film are changed by applying a desired voltage to the nano-carbon laminated film forming the solid-state imaging element. This makes it possible to perform imaging in the ranges from the near-infrared region to the visible light region and allows an amount of light incident on the photoelectric conversion section of the solid-state imaging element to be adjusted.

An electronic apparatus according to an embodiment of the present disclosure includes: a solid-state imaging element including a photoelectric conversion section; a shutter device disposed on a side of a light receiving surface of the solid-state imaging element; and a signal processing circuit for processing an output signal output from the solid-state imaging element. The shutter device is the shutter device according to the above-described embodiment of the present disclosure.

In the electronic apparatus according to the embodiment of the present disclosure, the shutter device includes a nano-carbon laminated film, and an amount of light received can be adjusted by applying voltage to the nano-carbon laminated film.

According to the present disclosure, it is possible to obtain a solid-state imaging element that can perform imaging in the ranges from the near-infrared region to the visible light region and which allows an amount of received light to be adjusted, a calibration method of the solid-state imaging element, and an electronic apparatus using the solid-state imaging element. In addition, according to the present disclosure, it is possible to obtain a shutter device whose light transmission characteristics are improved and an electronic apparatus using the shutter device.

### BRIEF DESCRIPTION OF THE DRAWINGS

FIGS. 1A to 1D are diagrams schematically showing variations in forbidden band in relation to variations in Fermi levelin a band structure of graphene;

FIG. 2 is a diagram showing changes in transmittance in an infrared region in a case where a single layer of graphene in the shape of a film is sandwiched between a pair of electrodes and voltage applied to the layer of graphene is changed;

FIG. 3 is a schematic block diagram showing the whole of a solid-state imaging element according to a first embodiment of the present disclosure;

FIG. 4 is a schematic sectional view of four pixels of the solid-state imaging element according to the first embodiment of the present disclosure;

FIG. 5 is a diagram showing a layout of a light receiving surface of the solid-state imaging element according to the first embodiment of the present disclosure;

FIG. 6 is a diagram showing output signal strength of an IR pixel with respect to exposure time;

FIG. 7 is a diagram schematically showing signal strength in the IR pixel in the solid-state imaging element according to the first embodiment of the present disclosure;

FIG. 8A is a diagram schematically showing signal strength before correction in a green pixel in the solid-state imaging element according to the first embodiment of the present disclosure, and FIG. 8B is a diagram schematically showing signal strength after the correction in the green pixel in the solid-state imaging element according to the first embodiment of the present disclosure;

FIG. 9 is a schematic sectional view of four pixels of a solid-state imaging element according to a first modification;

FIG. 10 is a schematic sectional view of a nano-carbon laminated film according to a second modification;

FIG. 11 is a schematic diagram of assistance in explaining changes in signal strength of light passing through nano-carbon layers when a material for a dielectric layer of the nano-carbon laminated film according to the second modification is changed;

FIG. 12 is a diagram showing relation between wavelengths of transmissible light and transmittance in the nano-carbon laminated film;

FIG. 13 is a diagram showing relation between wavelengths of transmissible light and transmittance in the nano-carbon laminated film;

FIG. 14 is a diagram showing relation between wavelengths of transmissible light and transmission ratios in the nano-carbon laminated film;

FIG. 15 is a schematic sectional view of a nano-carbon laminated film according to a third modification;

FIG. 16 is a schematic sectional view of a nano-carbon laminated film according to a fourth modification;

FIGS. 17A to 17C are process views of a method for manufacturing the nano-carbon laminated films according to the second to fourth modifications (first views);

FIGS. 18A to 18C are process views of the method for manufacturing the nano-carbon laminated films according to the second to fourth modifications (second views);

FIG. 19 is a sectional constitutional view of a solid-state imaging element according to a second embodiment of the present disclosure;

FIG. 20A is a diagram showing a layout of a light receiving surface of the solid-state imaging element when a color filter layer is a red filter, FIG. 20B is a diagram showing a layout of a light receiving surface of the solid-state imaging element when the color filter layer is a green filter, and FIG. 20C is a diagram showing a layout of a light receiving surface of the solid-state imaging element when the color filter layer is a white filter;

FIG. 21 is a schematic sectional view of four pixels of a solid-state imaging element according to a third embodiment of the present disclosure;

FIG. 22 is a schematic constitutional diagram of an imaging device according to a fourth embodiment of the present disclosure;

FIG. 23 is a sectional constitutional view showing in enlarged dimension a solid-state imaging element used in the imaging device according to the fourth embodiment of the present disclosure;

FIG. 24A is a plan constitutional view of a first electrode and a second electrode in a shutter device according to the fourth embodiment of the present disclosure when the first electrode and the second electrode are superposed on each other, and FIG. 24B is a plan constitutional view separately showing the first electrode and the second electrode in the shutter device according to the fourth embodiment of the present disclosure as an upper part and a lower part;

FIG. 25A is a diagram showing relation of the magnitude of voltage and the transmittance of light to one frame period in a case where the shutter device is made to perform pulse application of voltage, and FIG. 25B is a diagram showing relation of an amount of pixel-accumulated charge to the one frame period in the case where the shutter device is made to perform the pulse application of the voltage (first diagrams);

FIG. 26A is a diagram showing relation of the magnitude of voltage and the transmittance of light to one frame period in a case where the shutter device is made to perform pulse application of voltage, and FIG. 26B is a diagram showing relation of an amount of pixel-accumulated charge to the one frame period in the case where the shutter device is made to perform the pulse application of the voltage (second diagrams);

FIG. 27 is a sectional constitutional view of an imaging device according to a fifth embodiment of the present disclosure;

FIG. 28 is a sectional constitutional view of an imaging device according to a sixth embodiment of the present disclosure;

FIG. 29A is a diagram showing change in the transmittance of light by a graphene laminated film when application voltage is changed at a time of an imaging inspection, and FIG. 29B is a diagram showing the transmittance of light at each pixel position when a voltage V2 is applied in a device capable of adjusting the application voltage for each pixel;

FIG. 30 is a schematic block diagram of an electronic apparatus according to a seventh embodiment of the present disclosure; and

FIG. 31 is a schematic block diagram of an electronic apparatus according to an eighth embodiment of the present disclosure.

### DETAILED DESCRIPTION OF THE PREFERRED EMBODIMENTS

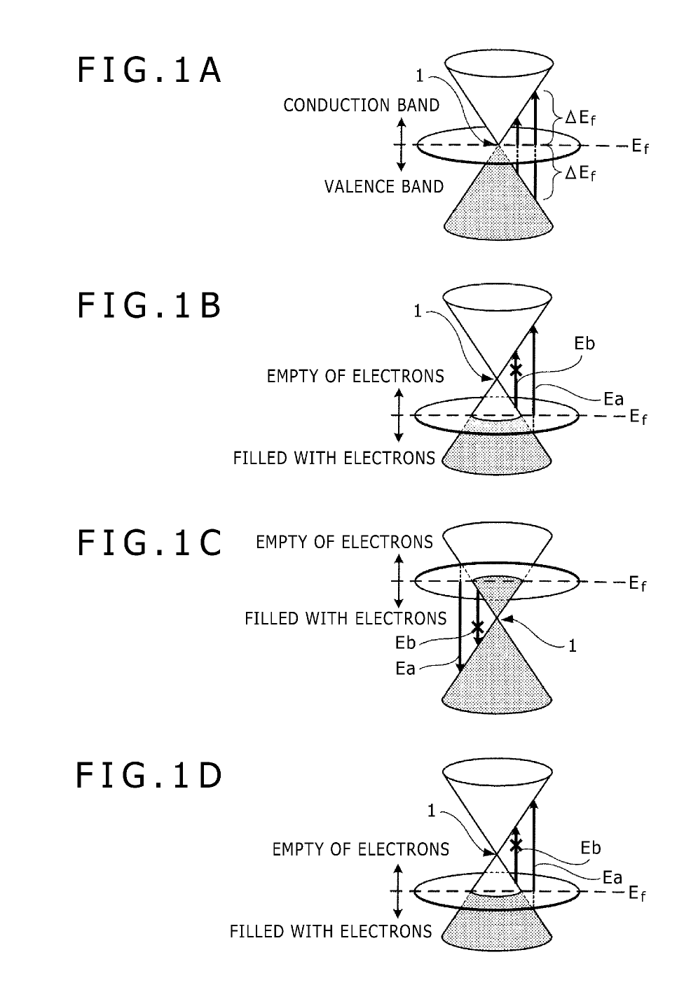

An example of a solid-state imaging element, a calibration method of a solid-state imaging element, a shutter device, and an electronic apparatus according to embodiments of the present disclosure will be described with reference to FIGS. 1A to 31. The embodiments of the present disclosure will be described in the following order. Incidentally, the present disclosure is not limited to the following examples.

1. First Embodiment: Example of Solid-State Imaging Element Having Filter Formed by Nano-Carbon Laminated Film over Light Receiving Section
2. Second Embodiment: Example of Solid-State Imaging Element Having Nano-Carbon Laminated Film Formed over Visible Light Pixel
3. Third Embodiment: Example of Solid-State Imaging Element Having Nano-Carbon Laminated Film Formed over Entire Surface

### 4. Fourth Embodiment: Imaging Device Including Shutter Device Having Nano-Carbon Laminated Film and Image Sensor

### 5. Fifth Embodiment: Imaging Device Including Shutter Device Having Nano-Carbon Laminated Film and Image Sensor

### 6. Sixth Embodiment: Imaging Device Including Shutter Device Having Nano-Carbon Laminated Film and Image Sensor

### 7. Seventh Embodiment: Electronic Apparatus Including Solid-State Imaging Element Having Nano-Carbon Laminated Film

8. Eighth Embodiment: Electronic Apparatus Including Imaging Device Having Nano-Carbon Laminated Film Prior to description of embodiments of the present technology, characteristics of a nano-carbon layer forming a nano-carbon laminated film applied to the present technology will be described. The following description will be made by taking graphene as an example of a nano-carbon material forming a nano-carbon layer. It has been known in the past that graphene is a very thin film-shaped material as a single layer of atoms, and is applicable to applications including electronic paper, touch panels, and the like. The application of graphene having such characteristics to electronic apparatuses is advantageous because graphene has a high transmittance of 97.7%, a low resistance value of 100Ω, and a small film thickness of 0.3 nm.

The proposers of the present technology et al. have proposed techniques for using graphene as a transparent conductive film, utilizing the high transmittance and high conductivity of graphene among these characteristics. As another characteristic of graphene, graphene has a feature of being changed in transmittance by application of voltage. FIGS. 1A to 1D are diagrams schematically showing variations in forbidden band in relation to variations in Fermi level E_{f} in a band structure of graphene.

As shown in FIG. 1A, unlike an ordinary semiconductor, graphene is a zero-gap semiconductor whose valence band and conduction band have a linear dispersion relation to each other with a Dirac point 1 as a point of symmetry. Normally, the Fermi level E_{f} is present at the Dirac point 1, but can be shifted by application of voltage or a doping process. For example, as shown in FIG. 1B, when the Fermi level E_{f} is moved by application of voltage or a doping process, an optical transition of energy higher than 2|ΔE_{f}| is possible, as indicated by an arrow Ea, for example. On the other hand, as indicated by an arrow Eb, an optical transition of energy equal to or lower than 2|ΔE_{f}| can be forbidden. Thus, the transmittance of graphene for light of a specific frequency can be changed by shifting the Fermi level E_{f}.

As shown in FIG. 1C, when graphene is doped with an n-type impurity, the Fermi level E_{f} can be shifted from the Dirac point 1 to the conduction band. In addition, as shown in FIG. 1D, when graphene is doped with a p-type impurity, the Fermi level E_{f} can be shifted from the Dirac point 1 to the valence band.

In addition, Chen et al. reported that the transmittance of graphene in an infrared region changes when voltage is applied to the graphene (Nature 471, 617-620 (2011)).

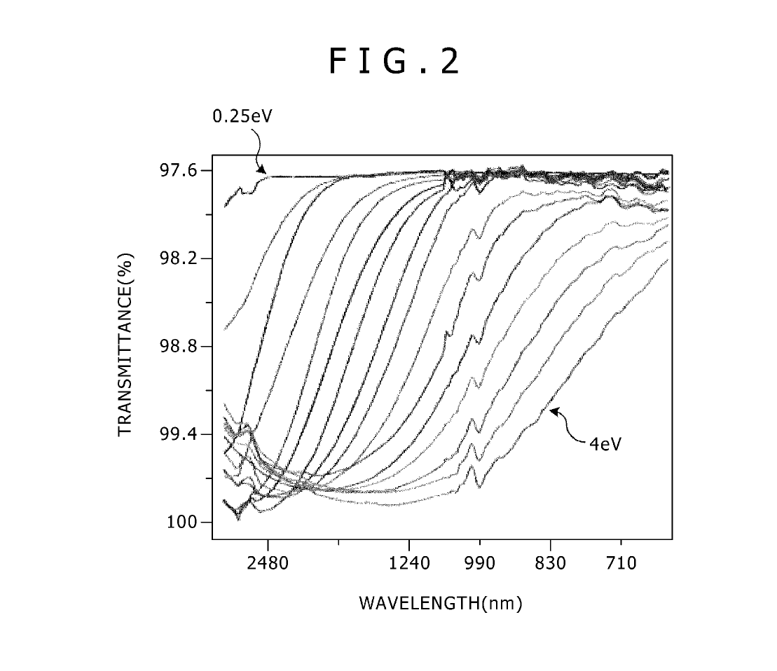

FIG. 2 shows a result of an experiment made on the basis of the report. FIG. 2 shows changes in transmittance in the infrared region in a case where a single layer of graphene in the shape of a film is sandwiched between a pair of electrodes and the applied voltage is changed. In FIG. 2, an axis of abscissas indicates wavelength (nm), and an axis of ordinates indicates transmittance (%). As shown in FIG. 2, suppose that the applied voltage is changed in a range of 0.25 eV to 4 eV, and that the axis of ordinates of the graph indicates a transmittance of 100% at a bottom and indicates a transmittance of 97.6% at a top (amount absorbed by one layer of graphene). That is, the higher the position on the axis of ordinates, the lower the transmittance in the graph. According to this graph, it is shown that in an overall wavelength region measured, as the applied voltage is changed in an increasing direction, the transmittance in a region of long wavelengths on the axis of abscissas of the graph becomes closer to 100% than in a region of short wavelengths. Further, it is shown that the higher the applied voltage, the more a region in which the transmittance becomes closer to 100% is extended to a short-wavelength side, and that therefore a wavelength region of light in which the transmittance can be modulated can be extended to the short-wavelength side by the applied voltage. This result is obtained in a single layer of atoms. However, the transmittance can be thus made variable in wavelength regions from a near-infrared region to the infrared-region to a terahertz region according to the magnitude of the applied voltage. In addition, these characteristics are common to not only graphene but also other nano-carbon materials such as carbon nanotubes and the like. In the present technology, attention is directed to characteristics of the nano-carbon materials, and devices using a nano-carbon laminated film having nano-carbon layers as a light control film are proposed.

### First Embodiment

### Example of Solid-State Imaging Element

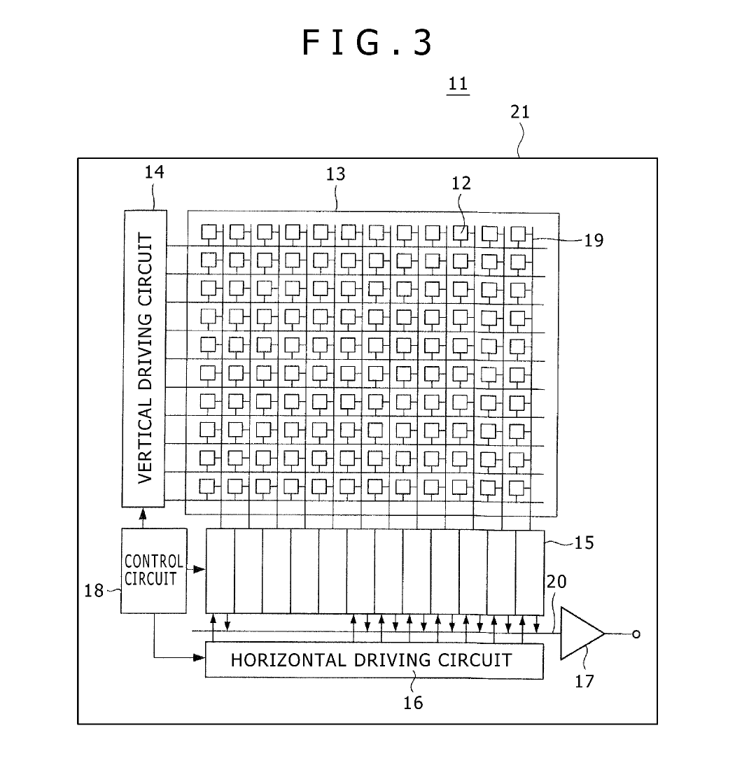

FIG. 3 is a schematic block diagram showing the whole of a solid-state imaging element 11 according to a first embodiment of the present disclosure. The solid-state imaging element 11 according to the example of the present embodiment includes a pixel section 13 formed by a plurality of pixels 12 arranged on a substrate 21 made of silicon, a vertical driving circuit 14, column signal processing circuits 15, a horizontal driving circuit 16, an output circuit 17, a control circuit 18, and the like. The pixels 12 include a photoelectric conversion section formed by a photodiode, a charge accumulating capacitance section, and a plurality of MOS transistors, and the plurality of pixels 12 are arranged regularly in the form of a two-dimensional array on the substrate 21. The MOS transistors forming the pixels 12 may be four MOS transistors, that is, a transfer transistor, a reset transistor, a selecting transistor, and an amplifying transistor, or may be the three MOS transistors excluding the selecting transistor.

The pixel section 13 is formed by the plurality of pixels 12 arranged regularly in the form of a two-dimensional array. The pixel section 13 includes an effective pixel region that actually receives light, amplifies a signal charge generated by photoelectric conversion, and outputs the signal charge to the column signal processing circuits 15 and a black reference pixel region (not shown) for outputting an optical black serving as a reference for a black level. The black reference pixel region is usually formed on the periphery of the effective pixel region.

The control circuit 18 generates a clock signal serving as a reference for operation of the vertical driving circuit 14, the column signal processing circuits 15, the horizontal driving circuit 16, and the like as well as a control signal and the like on the basis of a vertical synchronizing signal, a horizontal synchronizing signal, and a master clock. The clock signal, the control signal, and the like generated by the control circuit 18 are then input to the vertical driving circuit 14, the column signal processing circuits 15, the horizontal driving circuit 16, and the like.

The vertical driving circuit 14 is formed by a shift register, for example. The vertical driving circuit 14 sequentially selects and scans the pixels 12 of the pixel section 13 in a vertical direction in row units. Then, pixel signals based on signal charges generated according to amounts of light received in the photodiode of the respective pixels 12 are supplied to the column signal processing circuits 15 via vertical scanning lines 19. The column signal processing circuits 15 are for example arranged for each column of the pixels 12. The column signal processing circuits 15 subject the signals output from the pixels 12 of one row to signal processing such as noise removal, signal amplification, and the like on a pixel-column-by-pixel-column basis, based on a signal from the black reference pixel region (which is not shown, but is formed on the periphery of the effective pixel region). Horizontal selecting switches (not shown) are provided between output stages of the column signal processing circuits 15 and a horizontal signal line 20. The horizontal driving circuit 16 is for example formed by a shift register. The horizontal driving circuit 16 sequentially outputs a horizontal scanning pulse, and thereby selects each of the column signal processing circuits 15 in order, to make the pixel signals output from each of the column signal processing circuits 15 to the horizontal signal line 20.

The output circuit 17 subjects the signals sequentially supplied from each of the column signal processing circuits 15 to the output circuit 17 via the horizontal signal line 20 to signal processing, and outputs the signals.

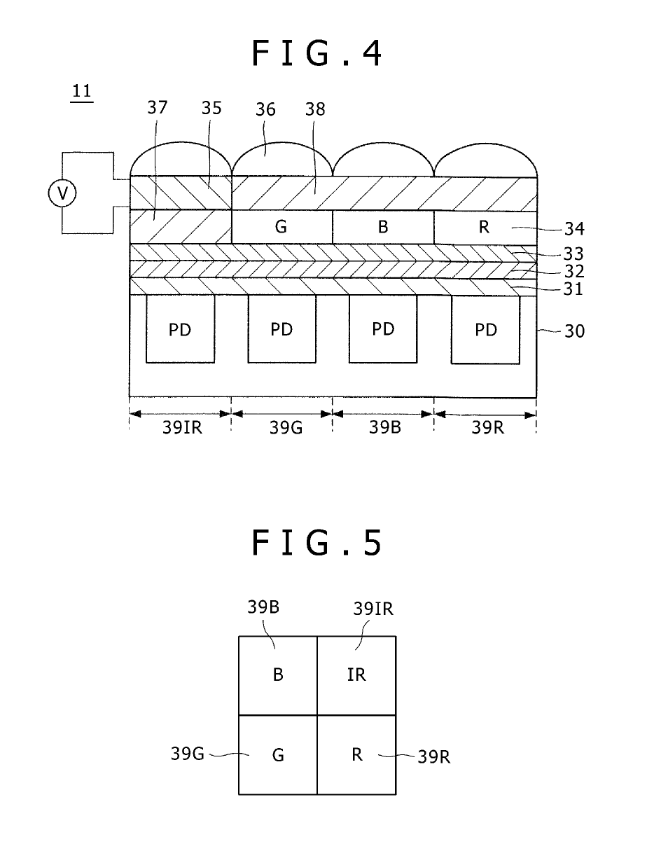

Description will next be made of a sectional constitution of the pixel section 13 in the solid-state imaging element 11 according to the example of the present embodiment. FIG. 4 is a schematic sectional view of four pixels of the solid-state imaging element 11 according to the example of the present embodiment. FIG. 5 is a diagram showing a layout of a light receiving surface of the solid-state imaging element 11 according to the example of the present embodiment.

As shown in FIG. 4, the solid-state imaging element 11 according to the example of the present embodiment includes a substrate 30, an interlayer insulating film 31, a protective film 32, a planarizing film 33, color filter layers 34, a nano-carbon laminated film 35, a condensing lens 36, a first transparent film 37, and a second transparent film 38.

The substrate 30 is formed by a semiconductor made of silicon. Photoelectric conversion sections PD formed by a photodiode are formed in desired regions on a light incidence side of the substrate 30. In the photoelectric conversion sections PD, incident light is subjected to photoelectric conversion, and signal charges are thereby generated and accumulated.

The interlayer insulating film 31 is formed by a SiO₂ film, and is formed on the substrate 30 including the photoelectric conversion sections PD. Other desired films such for example as the protective film 32 and the planarizing film 33 for surface planarization are formed. The color filter layers 34 are formed on the planarizing film 33, and are formed in a region other than that of an

IR (infrared) pixel (infrared pixel) to be described later. In the example of the present embodiment, the respective color filter layers 34 for R (red), G (green), and B (blue) are formed for each pixel, and an IR pixel 39IR without the color filter layers 34 is provided with the first transparent film 37 transmitting light in all wavelength regions in the same layer as the color filter layers 34. This first transparent film 37 is a film for eliminating a difference in level of an element surface which difference results from the color filter layers 34 not being formed, and is provided as required. The nano-carbon laminated film 35 is provided on the first transparent film 37. That is, in the present embodiment, the nano-carbon laminated film 35 is provided in the pixel without the color filter layers 34. The nano-carbon laminated film 35 includes a plurality of nano-carbon layers laminated in a direction of incidence of light. In the present embodiment, graphene is used as a nano-carbon layer forming the nano-carbon laminated film 35. In addition, a voltage power supply V is connected to the nano-carbon laminated film 35 via wiring. When voltage is not applied to graphene, the graphene absorbs 2.3% of light per layer. Hence, when the nano-carbon laminated film 35 is formed by laminating 40 layers of graphene, for example, 2.3×40 (=92) percent of light is absorbed. Thus, the transmittance of the nano-carbon laminated film 35 when voltage is not applied to the nano-carbon laminated film 35 is 8%. On the other hand, as described with reference to FIGS. 1A to 2, when a predetermined voltage (for example 5V) is applied to the graphene, the transmittance for light in the near-infrared region can be made to be substantially 100%. Therefore, when the nano-carbon laminated film 35 is formed by laminating 40 layers of graphene, the transmittance can be changed from 8% to 100% by changing the voltage from 0 V (off) to 5 V (on). Further, as shown in FIG. 2, the wavelength region of light in which region the transmittance of graphene can be modulated is changed according to the magnitude of the applied voltage. Hence, the wavelength region of transmissible light can be changed from the near-infrared region to the terahertz region by adjusting the number of laminated layers of graphene and changing the magnitude of the voltage applied to the nano-carbon laminated film 35.

As described above, the present embodiment makes it possible to change the transmittance of light and change the wavelength region of transmissible light from the near-infrared region to the terahertz region by changing the magnitude of the applied voltage applied from the voltage power supply V to the nano-carbon laminated film 35.

In addition, in the present embodiment, the pixels without the nano-carbon laminated film 35 are provided with the second transparent film 38 for transmitting light in all wavelength regions in the same layer as the nano-carbon laminated film 35. This second transparent film 38 is a film for eliminating a difference in level of an element surface which difference results from the nano-carbon laminated film 35 not being laminated, and is provided as required.

One layer of the nano-carbon laminated film 35 is formed by graphene of about 0.3 nm, so that the layer thickness of the nano-carbon laminated film 35 can be on the order of nanometers. Therefore, when the nano-carbon laminated film 35 is sufficiently thin, the second transparent film 38 does not need to be formed.

In the present embodiment, the pixel having the color filter layer of R (red) will be referred to as a red pixel 39R, the pixel having the color filter layer of G (green) will be referred to as a green pixel 39G, and the pixel having the color filter layer of B (blue) will be referred to as a blue pixel 39B. In addition, the pixel not provided with the color filter layers 34 but provided with the nano-carbon laminated film 35 will be referred to as an IR pixel 39IR. The IR pixel 39IR can obtain a signal based on light from the infrared region to the terahertz region.

The condensing lens 36 is formed over the nano-carbon laminated film 35 and the color filter layers 34, and has a surface in a convex shape for each pixel. Incident light is condensed by the condensing lens 36 to be made incident on the photoelectric conversion section PD of each pixel efficiently.

In the solid-state imaging element 11 according to the present embodiment, as shown in FIG. 5, four pixels, that is, the red pixel 39R, the blue pixel 39B, the green pixel 39G, and the IR pixel 39IR disposed so as to be adjacent to each other in two horizontal rows and two vertical columns form one unit pixel. The red pixel 39R obtains a signal according to light in the wavelength region of red. The green pixel 39G obtains a signal according to light in the wavelength region of green. The blue pixel 39B obtains a signal according to light in the wavelength region of blue. The IR pixel 39IR obtains a signal according to light in the near-infrared region. In the solid-state imaging element 11 according to the present embodiment, a dynamic range is extended in the IR pixel 39IR by providing the nano-carbon laminated film 35 on a light receiving side in the IR pixel 39IR. Further, in the solid-state imaging element 11 according to the present embodiment, a function of removing a noise signal caused by dark current from the red pixel 39R, the green pixel 39G, and the blue pixel 39B (noise cancelling function) can be imparted by providing the IR pixel 39IR. Description will next be made of the extension of the dynamic range and the noise cancelling function in the solid-state imaging element 11 according to the present embodiment.

### [Extension of Dynamic Range]

A dynamic range is expressed as a ratio between a saturation signal amount as a maximum signal amount and noise. The larger the dynamic range becomes, the more reliably a signal in a bright scene and a signal in a dark scene can be obtained. In the solid-state imaging element 11 according to the present embodiment, the transmittance of light passing through the nano-carbon laminated film 35 can be changed by varying the magnitude of the voltage applied to the nano-carbon laminated film 35 and the number of laminated layers of graphene forming the nano-carbon laminated film 35 in the IR pixel 39IR. Thereby the dynamic range can be extended.

As described above, when voltage is not applied to the nano-carbon laminated film 35, the nano-carbon laminated film 35 absorbs an amount of light which amount is a product of 2.3% as light absorptance per layer of graphene multiplied by the total number n of layers of graphene laminated within the nano-carbon laminated film 35. Therefore, the transmittance when voltage is not applied to the nano-carbon laminated film 35 can be adjusted by the number of laminated layers of graphene in the nano-carbon laminated film 35.

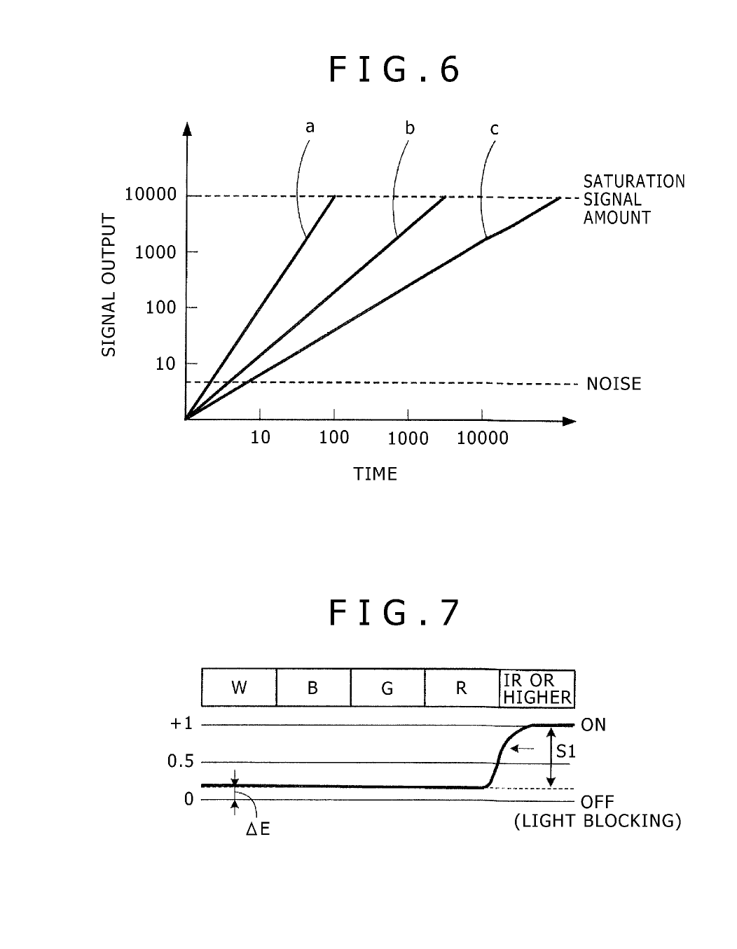

FIG. 6 is a diagram showing output signal strength of the IR pixel with respect to exposure time. FIG. 6 shows output signals when respective nano-carbon laminated films 35 having different numbers of laminated layers of graphene are used. The number of laminated layers of graphene forming the nano-carbon laminated film 35 is increased in order of irradiation curves a, b, and c shown in FIG. 6. FIG. 6 shows characteristics when voltage is not applied to the nano-carbon laminated film 35.

As shown in FIG. 6, the larger the number of laminated layers of graphene included in the nano-carbon laminated film 35, the lower the transmittance, and thus the longer the time taken to reach an amount of saturation charge, in order of the irradiation curves a, b, and c. Thus, the dynamic range when voltage is not applied can be adjusted by adjusting the number of laminated layers of graphene forming the nano-carbon laminated film 35. On the other hand, the transmittance of the nano-carbon laminated film 35 can be made to be substantially 100% by applying a predetermined voltage to the nano-carbon laminated film 35. Therefore, the transmittance of the nano-carbon laminated film 35 at a bright time and a dark time can be adjusted according to whether or not voltage is applied to the nano-carbon laminated film 35. For example, description will be made of a case where imaging is performed using the IR pixel 39IR configured such that the transmittance of the nano-carbon laminated film 35 when voltage is not applied is 20% and configured such that the transmittance of the nano-carbon laminated film 35 when voltage is applied is 98%. When photographing is performed in a very bright scene, signal output is saturated in a short time in an ordinary pixel. Accordingly, in imaging in a bright scene, voltage is not applied to the nano-carbon laminated film 35, and a signal obtained by imaging in the pixel of low light transmittance is used.

On the other hand, a slight amount of signal output is obtained in imaging in a dark scene during a nighttime or inside a room, for example. Accordingly, in imaging in a dark scene, a predetermined voltage is applied to the nano-carbon laminated film 35, whereby the transmittance is increased to 98% to perform the imaging. This increases sensitivity and provides a sufficient signal amount even in a dark scene.

An ordinary ND (Neutral Density) filter has a fixed slope in the graph, and does not allow a rate of extension of the dynamic range to be changed (the slope in the graph corresponds to one of a, b, and c in FIG. 6). On the other hand, the present embodiment allows the rate of extension of the dynamic range to be changed by adjusting the number of laminated layers of graphene forming the nano-carbon laminated film 35 (either of a, b, and c in FIG. 6 is possible by changing the number of laminated layers).

### [Noise Cancelling Function]

The noise cancelling function for correcting dark current nonuniformity will next be described in detail. A dark current is noise caused by an output current and a charge generated by heat even when light is blocked completely. When the noise cancelling function is imparted to the solid-state imaging element 11, a nano-carbon laminated film whose light transmittance when voltage is not applied is substantially 0% and whose light transmittance when voltage is applied is substantially 100% is used as the nano-carbon laminated film 35. In this case, when voltage is not applied to the nano-carbon laminated film 35, the IR pixel 39IR does not transmit light, and therefore a signal component obtained from the IR pixel 39IR is only a noise component ΔE resulting from a dark current. When the noise caused by the dark current is subtracted from the respective signal components of the red pixel 39R, the blue pixel 39B, and the green pixel 39G, noise signals resulting from the dark current can be removed in the respective pixels.

For example, description will be made of an example in which noise caused by the dark current is removed from the signal component of the green pixel 39G in the solid-state imaging element 11 according to the present embodiment. FIG. 7 is a diagram schematically showing signal strength in the IR pixel 39IR in the solid-state imaging element 11 according to the present embodiment.

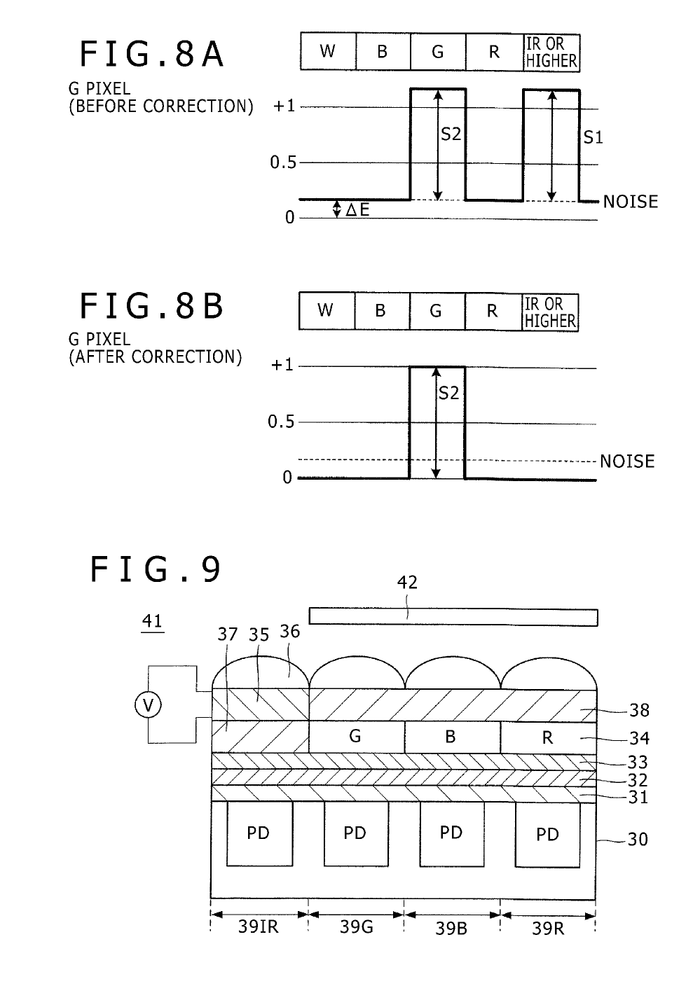

FIG. 8A is a diagram schematically showing signal strength before correction in the green pixel 39G in the solid-state imaging element 11 according to the example of the present embodiment. FIG. 8B is a diagram schematically showing signal strength after correction in the green pixel 39G in the solid-state imaging element 11 according to the example of the present embodiment.

In FIG. 7, an “OFF” denotation on the graph indicates a signal level when voltage is not applied to the nano-carbon laminated film 35, and an “ON” denotation on the graph indicates a signal level when voltage is applied to the nano-carbon laminated film 35. When voltage is applied to the nano-carbon laminated film 35, that is, at an “ON” time, the transmittance of the nano-carbon laminated film 35 is substantially 100%. Therefore, when voltage is turned on, as shown in FIG. 7, the IR pixel 39IR obtains a signal component S1 in regions equal to and higher than the infrared region. When voltage is not applied to the nano-carbon laminated film 35, that is, at an “OFF” time, the transmittance of the nano-carbon laminated film 35 is substantially 0%. Therefore, when voltage is turned off, the IR pixel 39IR obtains only the noise component ΔE resulting from the dark current. Meanwhile, as shown in FIG. 8A, the green pixel 39G obtains a signal component S2 in the green region through the G (green) color filter. The green pixel 39G also transmits light in the infrared region. Thus, the signal component S1 in the infrared region and the noise component ΔE resulting from the dark current are added to a signal component read out from the green pixel 39G. That is, the signal component SG read out from the green pixel 39G is (signal component S2 in the green region)+(signal component S1 in the regions equal to and higher than the infrared region)+(noise component ΔE resulting from the dark current).

Therefore, the signal component S2 in the green region can be obtained by subtracting the signal component S1 of the IR pixel 39IR when the application voltage is turned on and the noise component ΔE of the IR pixel 39IR when the application voltage is turned off from the total signal component SG of the green pixel 39G. Thereby, both of the infrared component and the noise component ΔE can be removed from the signal component SG read out from the green pixel 39G. Incidentally, each signal component is read out from each pixel as a signal amount converted into a charge, and therefore the above-described subtraction applied to the signal components are performed as subtraction applied to signal amounts read out from the respective pixels. The same applies in the following.

The above description has been made of the green pixel 39G. However, the infrared component and the noise component ΔE of the red pixel 39R and the blue pixel 39B can be similarly removed. Thus, in the present embodiment, both of the infrared component and the noise component ΔE can be removed from the visible light pixels using the signal component obtained in the IR pixel 39IR, so that there is no need to provide an IR cutoff filter over the visible light pixels. Therefore the element can be miniaturized.

In addition, when no IR cutoff filter is provided over the IR pixel, but an IR cutoff filter is provided only over the visible light pixels, patterning of the IR cutoff filter is necessary, and the number of processes is increased. In contrast to this, the present embodiment does not need the IR cutoff filter, and can therefore reduce the number of processes.

The above description has been made by taking as an example a case where no IR cutoff filter is provided over the visible light pixels. However, noise can be removed by using the signal component obtained in the IR pixel even when an IR cutoff filter is provided over the visible light pixels. The following description will be made of an example in which an IR cutoff filter is provided over the visible light pixels as a first modification.

### [First Modification]

FIG. 9 is a schematic sectional view of four pixels of a solid-state imaging element 41 according to the first modification.

In FIG. 9, parts corresponding to those of FIG. 4 are identified by the same reference symbols, and repeated description thereof will be omitted. As shown in FIG. 9, the solid-state imaging element 41 according to the modification has an IR cutoff filter 42 over a red pixel 39R, a green pixel 39G, and a blue pixel 39B other than an IR pixel 39IR.

The solid-state imaging element 41 cuts off light of wavelengths in the infrared region in the red pixel 39R, the green pixel 39G, and the blue pixel 39B provided with the IR cutoff filter 42. Therefore, signal components obtained in the visible light pixels are signal components resulting from light in the visible light region, but include a noise component ΔE resulting from a dark current.

Accordingly, the solid-state imaging element 41 also corrects dark current nonuniformity using the signal component of the IR pixel 39IR. Also in the following, description will be made of an example in which the noise component ΔE resulting from the dark current is removed from the signal component of the green pixel 39G in the solid-state imaging element 41. In this case, a nano-carbon laminated film whose light transmittance when voltage is not applied is (substantially 0%) 0 to 20% and whose light transmittance when voltage is applied is (substantially 100%) 80 to 100% is used as a nano-carbon laminated film 35.

The green pixel 39G in the solid-state imaging element 41 according to the first modification has the IR cutoff filter 42 on the side of a light incidence surface. A signal component SG′ read out from the green pixel 39G therefore includes a signal component S2 in the green region and the noise component ΔE resulting from the dark current.

On the other hand, when voltage is not applied to the nano-carbon laminated film 35, the IR pixel 39IR does not transmit light, and therefore a signal obtained from the IR pixel 39IR is only the noise component ΔE resulting from the dark current.

Hence, the signal component S2 in the green region can be obtained by subtracting the noise signal component ΔE when the application voltage for the IR pixel 39IR is off from the total signal component SG' of the green pixel 39G provided with the IR cutoff filter 42. Incidentally, in the examples of FIG. 4 and FIG. 9, the nano-carbon laminated film 35 is provided between the color filter layer 34 and the condensing lens 36, but is not limited to this. It suffices for the nano-carbon laminated film 35 to be present between the photoelectric conversion section PD and the condensing lens 36. For example, the nano-carbon laminated film 35 may be provided between the color filter layer 34 and the substrate 30.

The solid-state imaging element 11 according to the foregoing first embodiment and the solid-state imaging element 41 described in the first modification have been described taking the nano-carbon laminated film 35 having the structure obtained by laminating a plurality of layers of graphene as an example. However, the constitution of the nano-carbon laminated film is not limited to this. Other examples of the nano-carbon laminated film will be described as a second to a fourth modification in the following.

### [Second Modification]

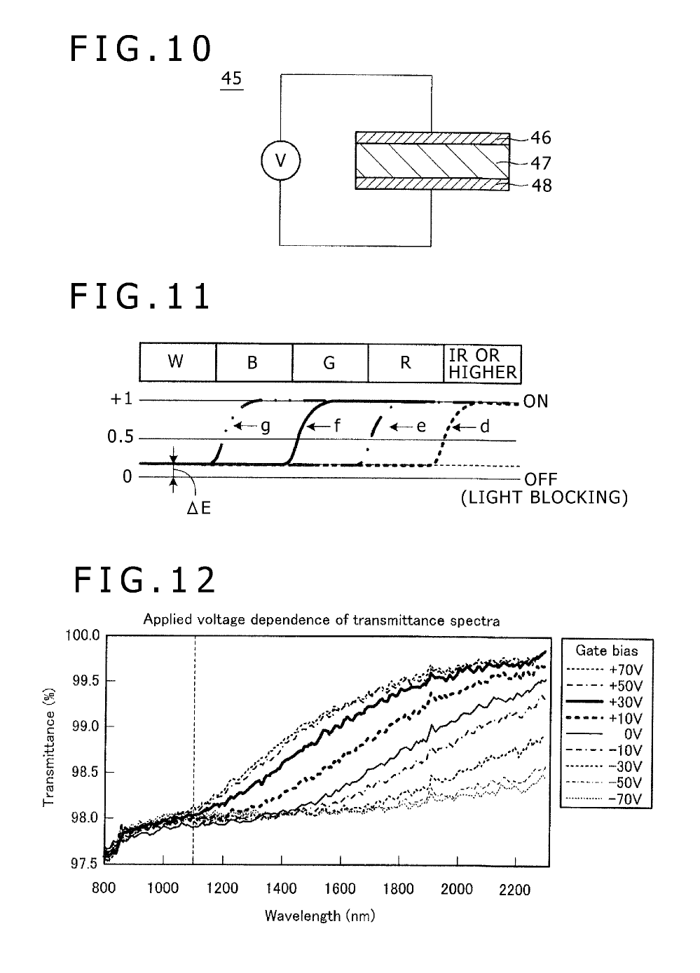

The nano-carbon laminated film can change a wavelength region of light that the nano-carbon laminated film can transmit (in which region transmittance can be modulated) and light transmittance thereof according to the constitution and material of the nano-carbon laminated film. FIG. 10 is a schematic sectional view of a nano-carbon laminated film according to a second modification. As shown in FIG. 10, the nano-carbon laminated film 45 includes a first electrode 46, a dielectric layer 47, and a second electrode 48.

The first electrode 46 and the second electrode 48 are each formed by one nano-carbon layer or a plurality of nano-carbon layers. In addition, in the second modification, graphene, for example, is used as the nano-carbon layers forming the first electrode 46 and the second electrode 48. A voltage power supply V is connected to the first electrode 46 and the second electrode 48 via wiring.

The dielectric layer 47 is provided between the first electrode 46 and the second electrode 48. Materials for the dielectric layer 47 used in the second modification include for example dielectric constant materials such as silicon oxide (SiO₂), aluminum oxide (Al₂O₃), calcium fluoride (CaF₂), InGaZnOx (IGZO), High Density Polyethylene (HDPE), and the like.

The dielectric layer 47 may also be formed of a high dielectric constant material having a high relative dielectric constant. For example, high dielectric constant materials for forming the dielectric layer 47 include hafnium oxide (HfO₂), strontium titanate (SrTiO₃: STO), zirconium oxide (ZrO₂), lead lanthanum zirconate titanate ((Pb, La)(Zr, Tr)O₃: PLZT), and the like. FIG. 11 is a diagram of assistance in explaining changes in signal strength of light passing through each nano-carbon laminated film 45 when the material for the dielectric layer 47 of the nano-carbon laminated film 45 according to the second modification is changed. In the following, a constitution whose transmittance is 100% when application voltage is on and whose transmittance is 0% when the application voltage is off will be illustrated, and modulation of a wavelength region of transmissible light by the constitution and material of the nano-carbon laminated film will be described.

As shown in FIG. 11, in a case where the nano-carbon laminated film 35 of only graphene (see FIG. 4) is used, light in regions equal to or higher than the infrared region (IR) as indicated by an arrow d can be transmitted when the voltage is on. On the other hand, in a case where the nano-carbon laminated film 45 having the constitution formed by sandwiching the dielectric layer 47 between the first electrode 46 and the second electrode 48 is used, the wavelength region of transmissible light can be extended to the visible light region when the voltage is on.

For example, in a case where the dielectric layer 47 in the nano-carbon laminated film 45 is formed of a normal dielectric constant material, the wavelength region of transmissible light can be extended to the red region (R) indicated by an arrow e when the voltage is on. Further, in a case where the dielectric layer 47 in the nano-carbon laminated film 45 is formed of a high dielectric constant material, the wavelength region of transmissible light can be extended to the range of the green region (G) or the blue region (B) indicated by an arrow f or g when the voltage is on. This is due to difference in relative dielectric constant between the materials for the dielectric layer 47. That is, the higher the relative dielectric constant of the dielectric layer 47 is, the more the wavelength region of transmissible light can be extended.

Table 1 below shows relation between materials for the dielectric layer 47 used in the nano-carbon laminated film 45, relative dielectric constants c, withstand voltages (MV/cm), and charge densities (mC/cm²).

TABLE 1

| | RELATIVE | WITHSTAND | CHARGE |
|---|---|---|---|
| | DIELECTRIC | VOLTAGE | DENSITY |
| MATERIAL | CONSTANTε | (MV/cm) | (mC/cm²) |
| Si0₂ | 4 | 10 | 3.5 |
| Al₂O₃ | 8.2 | 8.2 | 6 |
| IGZO | 9 | — | — |
| HfO₂ | 18.5 | 7.4 | 12 |
| ZrO₂ | 29 | 6 | 15.4 |
| HDPE | 2.3 | — | — |
| PLZT | 200 | 3 | 53.1 |
| CaF₂ | 6.6 | 0.3 | 0.17 |

In the following, description will be made of an example in which the wavelength region of transmissible light is extended by using Al₂O₃ and IGZO having different relative dielectric constants as shown in Table 1 above as the dielectric layer 47.

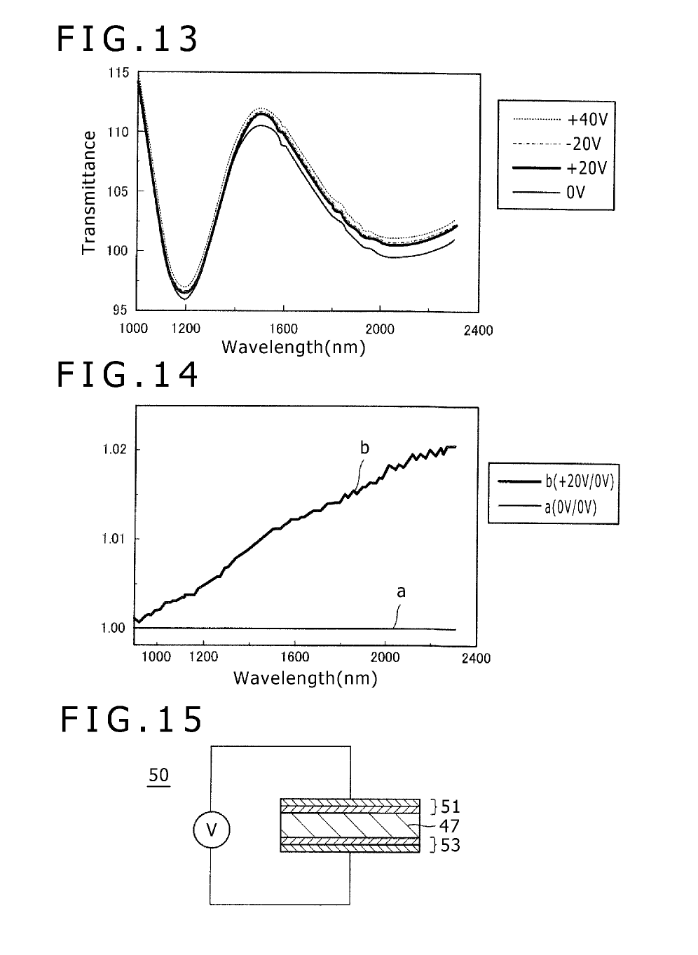

FIG. 12 and FIG. 13 show an example of the light transmission spectra of the nano-carbon laminated film 45.

FIG. 12 shows an example in which the dielectric layer 47 in the nano-carbon laminated film 45 is formed of Al₂O₃. In this case, the application voltage is changed in a range of −70 V to +70 V. An axis of ordinates of the graph indicates a transmittance of 97.5% at a bottom and a transmittance of 100% at a top.

FIG. 13 shows an example in which the dielectric layer 47 in the nano-carbon laminated film 45 is formed of IGZO. In this case, the application voltage is changed in a range of −20 V to +40 V. An axis of ordinates of the graph indicates a transmittance of 95% at a bottom and a transmittance of 115% at a top.

In addition, FIG. 14 is a graph obtained by processing FIG. 13 in order to describe changes in light transmission spectra according to the application voltage, and shows a spectral ratio α (0 V/0 V) and a spectral ratio b (+20 V/0 V) when a spectrum at an application voltage of 0 V in FIG. 13 is set as a reference.

As shown in FIG. 12, in the case where the material of the dielectric layer 47 is Al₂O₃, spectra at application voltages equal to and higher than +30 V (line of a medium thickness) exhibit a spectral rise from the vicinity of 1100 nm. That is, it is shown that the application voltage can extend the wavelength region of transmissible light (region in which transmittance can be modulated) to the vicinity of 1100 nm. On the other hand, as shown in FIG. 14, in the case where the material of the dielectric layer 47 is IGZO, a spectrum at an application voltage of +20 V (line of a medium thickness) exhibits a spectral rise from a shorter wavelength side than 1000 nm. That is, it is shown that the application voltage can extend the wavelength region of transmissible light to the shorter wavelength side than 1000 nm.

From Table 1 above, a comparison between the relative dielectric constants of IGZO and Al₂O₃ as materials for the dielectric layer 47 indicates that IGZO has a higher relative dielectric constant. It is thus shown that the higher the relative dielectric constant of the material of the dielectric layer 47, the shorter the wavelength to which side the application voltage shifts the wavelength of forbidden transition, and the shorter the wavelength to which side the wavelength region of transmissible light can be extended.

In addition, as shown in FIG. 12, it is shown that the higher the application voltage, the shorter the wavelength to which side the wavelength region of transmissible light can be extended. For example, it is show that an application voltage of 10 V can extend the wavelength region of transmissible light to the vicinity of 1200 nm, and that an application voltage of 30 V can extend the wavelength region of transmissible light to the vicinity of 1100 nm.

As described above, the nano-carbon laminated film 45 according to the second modification extends the wavelength region of transmissible light in addition to the effects of the nano-carbon laminated film 35 of only graphene (see FIG. 4), due to the constitution in which the dielectric layer 47 is sandwiched between the first electrode 46 and the second electrode 48. Further, the wavelength region of transmissible light can be set arbitrarily by selecting the material of the dielectric layer 47 sandwiched between the first electrode 46 and the second electrode 48. That is, the wavelength region of transmissible light can be extended to a shorter wavelength side by selecting a material having a higher relative dielectric constant as the material in the dielectric layer 47.

In addition, the nano-carbon laminated film 45 can modulate the wavelength region of transmissible light and the transmittance thereof also by the magnitude of the applied voltage.

### [Third Modification]

FIG. 15 is a schematic sectional view of a nano-carbon laminated film according to a third modification. As shown in FIG. 15, the nano-carbon laminated film 50 according to the third modification is different from the nano-carbon laminated film 45 shown in FIG. 10 only in that the nano-carbon laminated film 50 according to the third modification uses graphene doped with an impurity as a first electrode 51 and a second electrode 53. As shown in FIG. 15, the nano-carbon laminated film 50 includes the first electrode 51, a dielectric layer 47, and the second electrode 53. Therefore, similar constituent elements to those of the nano-carbon laminated film shown in FIG. 10 are identified by the same reference numerals, and repeated description thereof will be omitted.

The first electrode 51 and the second electrode 53 are each formed by one nano-carbon layer or a plurality of nano-carbon layers. In addition, in the third modification, graphene doped with an n-type impurity is used as the one nano-carbon layer or the plurality of nano-carbon layers forming the first electrode 51, and graphene doped with a p-type impurity is used as the second electrode 53. A voltage power supply V is connected to the first electrode 51 and the second electrode 53 via wiring. The n-type first electrode 51 is connected to the negative electrode side of the voltage power supply V. The p-type second electrode 53 is connected to the positive electrode side of the voltage power supply V.

A dielectric layer similar to the dielectric layer 47 in the nano-carbon laminated film 45 described with reference to FIG. 10 is applied as the dielectric layer 47. That is, the dielectric layer 47 is formed of a normal dielectric constant material or a high dielectric constant material as described above.

The nano-carbon laminated film 50 having such a constitution extends a transmissible wavelength range as follows. As shown in FIGS. 1A to 1D described above, the Fermi level E_{f} of graphene can be moved by the magnitude of applied voltage and doping with an impurity. A movable range of the Fermi level E_{f} corresponds to a part of the wavelength region of transmissible light in the nano-carbon laminated film 50. That is, when the Fermi level E_{f} of graphene used for the first electrode 51 and the second electrode 53 in the nano-carbon laminated film 50 is shifted by a doping process or the like, an amount of this shift corresponds to wavelength energy. The wavelength region of transmissible light in the nano-carbon laminated film 50 is extended by an amount of this wavelength energy.

That is, the wavelength region of transmissible light in the nano-carbon laminated film 50 can be extended by using the same material as the dielectric layer 47 in the nano-carbon laminated film 50 and using graphene doped with an impurity as the first electrode 51 and the second electrode 53.

Further, by using graphene doped with an impurity as the first electrode 51 and the second electrode 53, the nano-carbon laminated film 50 according to the third modification as described above can extend a transmittance modulation range, that is, the width of a range in which transmittance can be modulated, in addition to the effects of the second modification.

### [Fourth Modification]

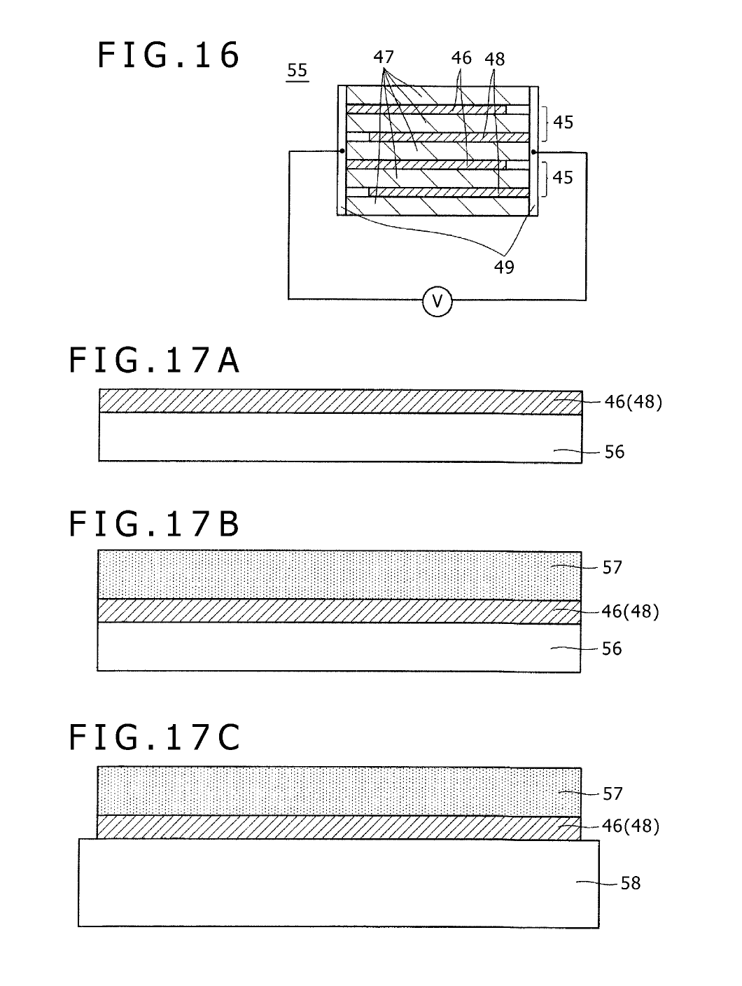

FIG. 16 is a schematic sectional view of a nano-carbon laminated film according to a fourth modification. As shown in FIG. 16, the nano-carbon laminated film 55 according to the fourth modification is an example in which the dielectric layer 47 and the nano-carbon laminated film 45 shown in FIG. 10 are alternately laminated. That is, the nano-carbon laminated film 55 according to the fourth modification is an example in which first electrodes 46, dielectric layers 47, and second electrodes 48 are alternately laminated, and in which surfaces at both ends in a direction of lamination are sandwiched between dielectric layers 47. Therefore, similar constituent elements to those of the nano-carbon laminated film shown in FIG. 10 are identified by the same reference numerals, and repeated description thereof will be omitted.

In this case, first electrodes, second electrodes, and dielectric layers similar to the first electrode 46, the second electrode 48, and the dielectric layer 47 of the nano-carbon laminated film 45 described with reference to FIG. 10 are applied as the first electrodes 46, the second electrodes 48, and the dielectric layers 47. Incidentally, as in the nano-carbon laminated film 50 described with reference to FIG. 15, the first electrodes and the second electrodes may be formed by using graphene doped with an impurity.

As shown in FIG. 16, leading electrodes 49 are connected respectively to end parts of the first electrodes 46 and the second electrodes 48 of the nano-carbon laminated film 55. A voltage power supply V is connected via these leading electrodes 49.

In the nano-carbon laminated film 55 according to the fourth modification as described above, the nano-carbon layers forming the first electrodes 46 and the second electrodes 48 and the dielectric layers 47 are alternately laminated. The nano-carbon laminated film 55 according to the fourth modification can thereby further extend a modulation range in addition to the effects of the third modification.

Incidentally, the solid-state imaging elements 11 and 41 according to the embodiment including the nano-carbon laminated films of the respective constitutions described above are not limited to the constitutions shown in the sectional views of FIG. 4 and FIG. 9, but materials, the order of lamination, and the like can be set variously so as to achieve desired functions and performance.

In addition, the solid-state imaging elements 11 and 41 according to the present embodiment use a device having Si-base photoelectric conversion sections PD as sensor parts, but are not limited to the Si-base device. For example, provisions can be made variously for organic photoelectric conversion films as photoelectric conversion sections PD, bolometer type devices, and the like. Also in this case, similar effects to those of the present embodiment can be obtained by providing a nano-carbon laminated film on the side of a light incidence surface.

### [Method for Manufacturing Nano-Carbon Laminated Film]

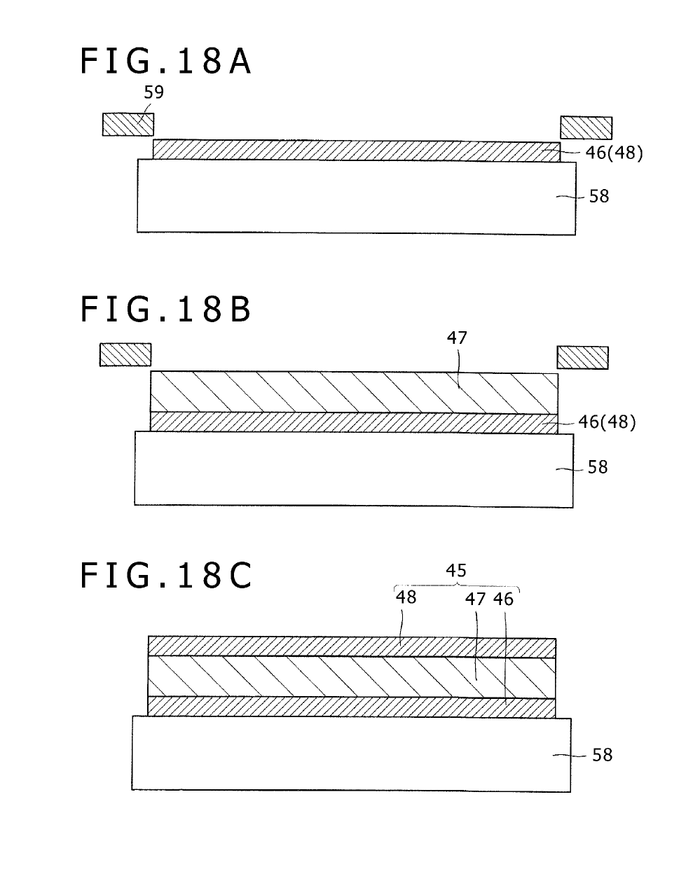

An example of a method for manufacturing the nano-carbon laminated films according to the second to fourth modifications will next be described with reference to FIGS. 17A to 17C and FIGS. 18A to 18C.

First, as shown in FIG. 17A, a first electrode 46 is formed on one principal surface of a copper foil 56. At this time, the rolled copper foil 56 having a thickness of 18 μm is placed in an electric furnace, and fired at 980° C. under a hydrogen atmosphere (hydrogen flow rate of 20 sccm). A methane gas is supplied for 30 minutes at a flow rate of 10 sccm. One nano-carbon layer is thereby formed as the first electrode 46 on the copper foil 56. Incidentally, the number of nano-carbon layers can be controlled by a film formation time. Next, though not shown herein, after the first electrode 46 is formed on the copper foil 56, the first electrode 46 is cut into a size of 23 mm×17 mm.

Next, as shown in FIG. 17B, an acetone dilute solution of polymethyl methacrylate (PMMA) is applied by spin coating onto the first electrode 46, and thereafter the acetone dilute solution is dried and removed. A PMMA film 57 is thereby formed on the first electrode 46.

Next, the copper foil 56 on which the first electrode 46 and the PMMA film 57 are formed is immersed in an iron nitrate aqueous solution for about 40 minutes to remove the copper foil 56.

As shown in FIG. 17C, a substrate 58 formed by a quartz wafer cut into 25 mm×25 mm and having a thickness of 1 mm is prepared, and the substrate 58 is laminated to an exposed surface side of the first electrode 46. Next, the first electrode 46 and the PMMA film 57 laminated to the substrate 58 are immersed in an acetone solvent for three minutes to remove the PMMA film 57. Thereafter, as shown in FIG. 18A, a metallic mask 59 having an opening of 23 mm×17 mm is disposed on the side of the first electrode 46 on the substrate 58. Next, as shown in FIG. 18B, after a temperature within the chamber is set to 200° C., a dielectric layer 47 formed of alumina oxide (Al₂O₃) is film-formed with a film thickness of 20 nm by an atomic layer deposition method on the first electrode 46 exposed within the opening of the metallic mask 59.

Next, as shown in FIG. 18C, a second electrode 48 is laminated onto the dielectric layer 47. At this time, as in the procedure described earlier with reference to FIG. 17A and FIG. 17B, the second electrode 48 coated with a PMMA film 57 is formed, and the second electrode 48 is transferred onto the dielectric layer 47. Thereafter, the substrate 58 having the second electrode 48 transferred thereto is immersed in an acetone solvent for three minutes to remove the PMMA film 57. Thereby the nano-carbon laminated film 45 according to the second modification can be formed.

When the nano-carbon laminated film 55 according to the fourth modification is fabricated, the processes described with reference to FIGS. 18A to 18C are repeated.

A dielectric layer 47 and a nano-carbon laminated film 45 are laminated on a nano-carbon laminated film 45. Thereafter, dielectric layers 47 are film-formed by the process described with reference to FIG. 18B such that surfaces at both ends in a direction of lamination of the above laminated structure are sandwiched between the dielectric layers 47.

The nano-carbon laminated film 55 is thus obtained. In addition, the nano-carbon laminated film 55 in the present embodiment has nine layers obtained by alternately laminating nano-carbon layers forming the first electrodes 46 and the second electrodes 48 and the dielectric layers 47. However, a nano-carbon laminated film further including a plurality of layers may be formed by repeating the processes of FIG. 18B and FIG. 18C. Thereafter, as shown in FIG. 16, leading electrodes 49 are formed by coating on end surfaces of the nano-carbon laminated film 55 so as to apply a positive potential and a negative potential, and a voltage power supply is connected.

Incidentally, in each film formation process, a method of continuous film formation by a roll-to-roll system or a method of locally heating an electrode and continuously film-forming graphene, for example, are applied.

As described above, according to the manufacturing method according to the present embodiment, a nano-carbon laminated film having a dielectric layer sandwiched between electrodes formed by nano-carbon layers can be obtained.

### 2. Second Embodiment

### Example of Solid-State Imaging Element

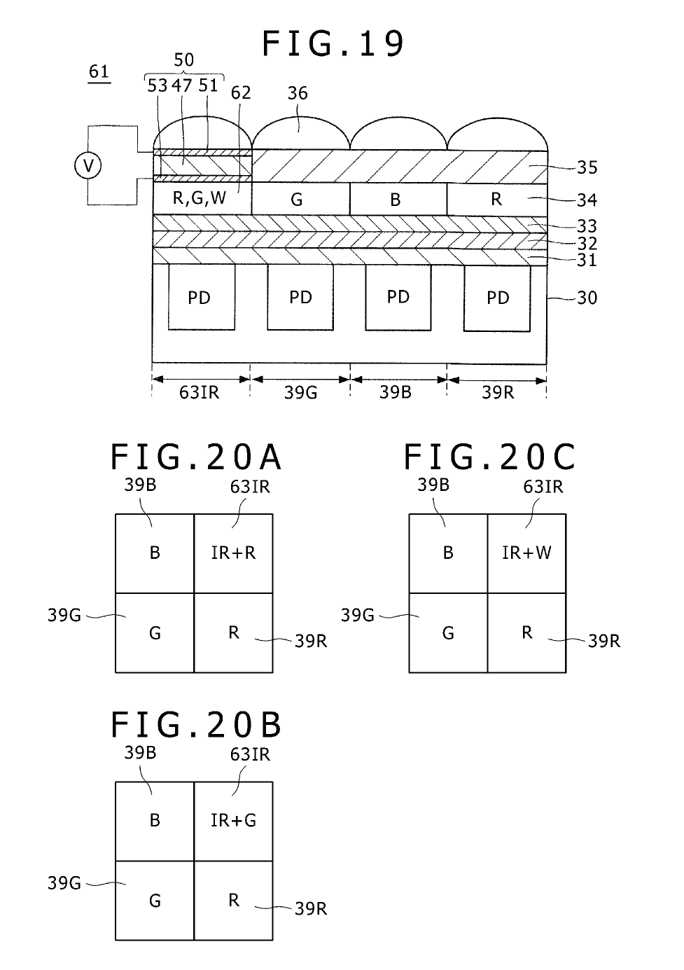

A solid-state imaging element according to a second embodiment of the present disclosure will next be described. FIG. 19 is a sectional view of a constitution of the solid-state imaging element 61 according to the example of the present embodiment. In FIG. 19, parts corresponding to those of FIG. 4 are identified by the same reference numerals, and repeated description thereof will be omitted. The solid-state imaging element 61 according to the example of the present embodiment is an example in which a color filter layer 62 is formed under a nano-carbon laminated film 50.

The nano-carbon laminated film 50 is similar to the nano-carbon laminated film 50 described with reference to FIG. 15. Specifically, the nano-carbon laminated film 50 in the present embodiment includes a first electrode 51, a dielectric layer 47, and a second electrode 53. Graphene doped with an n-type impurity is used as a nano-carbon layer forming the first electrode 51, and graphene doped with a p-type impurity is used as the second electrode 53. A voltage power supply V is connected to the first electrode 51 and the second electrode 53 via wiring. The nano-carbon laminated film 50 in the present embodiment is formed so as not to transmit light when voltage is not applied between the first electrode 51 and the second electrode 53, and so as to transmit visible light according to the value of a predetermined voltage when the voltage is applied between the first electrode 51 and the second electrode 53. Incidentally, the dielectric layer 47 is formed of a normal dielectric constant material or a high dielectric constant material as described above.

The color filter layer 62 can be a red filter, a green filter, or a white filter according to a use. The color filter layer 62 is provided on a planarizing film 33, and is provided in the same layer as color filter layers 34 for other pixels. Thus, in the present embodiment, a color filter transmitting visible light is provided in an IR pixel provided with the nano-carbon laminated film 50. Thereby, in the IR pixel 63IR, light is not made incident when voltage is not applied to the nano-carbon laminated film 50, and visible light of wavelengths corresponding to the optical transparency of the color filter layer 62 is transmitted when voltage is applied to the nano-carbon laminated film 50. In the following, description will be made of each of cases where the color filter layer 62 is a red filter, a green filter, and a white filter.

[2-1 Case where Red Filter is Used for IR Pixel]

Description will first be made of a case where a red filter is used as the color filter layer 62. In this case, the nano-carbon laminated film 50 is formed so as not to transmit light when voltage is not applied between the first electrode 51 and the second electrode 53, and so as to transmit light of wavelengths from the infrared region to the red region when a predetermined voltage (for example 10V) is applied between the first electrode 51 and the second electrode 53.

In the following description, the pixel provided with the nano-carbon laminated film 50 will be described as an IR +R pixel 63IR.

FIG. 20A is a diagram showing a layout of a light receiving surface of the solid-state imaging element 61 when the color filter layer 62 is a red filter. In this case, as shown in FIG. 20A, four pixels, that is, a red pixel 39R, a blue pixel 39B, a green pixel 39G, and the IR+R (red) pixel 63IR disposed so as to be adjacent to each other in two horizontal rows and two vertical columns form one unit pixel. The red pixel 39R obtains a signal component according to light in the red region. The green pixel 39G obtains a signal component according to light in the green region. The blue pixel 39B obtains a signal component according to light in the blue region. The IR+R pixel 63IR obtains signal components according to light in the infrared region and the red region only when voltage is applied to the nano-carbon laminated film 50.

Therefore, according to the solid-state imaging element 61 according to the present embodiment, the IR+R pixel 63IR obtains the signal component according to the light in the infrared region and the signal component according to the light in the red region as a visible light component as a result of the application of the voltage. This eliminates a problem of decrease in resolution because the provision of the IR pixel does not reduce visible light pixels. In addition, because transmittance can be changed by the application of the voltage, a measure can be taken against a decrease in resolution in high-sensitivity imaging in a dark scene during a nighttime or the like. Further, because the IR+R pixel 63IR serves both as an IR pixel and a red pixel, an amount of signal degradation of the green pixel 39G in imaging in a bright scene can be compensated by using a high-frequency component of a high-resolution signal in the red region which signal is obtained in the IR+R pixel 63IR. That is, a blurred color can be corrected by combining the high-frequency component of a sharp color. The output signal of a pixel desired to be corrected can be expressed by the following equation.

Output Signal=Received Signal+C1×High-Frequency Component of Red Pixel+C2×High-Frequency Component of Green Pixel+C3×High-Frequency Component of Blue Pixel

where C1, C2, and 3C are a coefficient. The coefficients are determined according to the signal at the position to be corrected.

In the example of the present embodiment, the above coefficients are set such that C1=0.50, C2=0.48, and C3=0.02, and the signal of the green pixel is corrected by using the high-frequency component of red. This signal processing can improve a blurred part of the image. In addition, in the solid-state imaging element 61 according to the present embodiment, as in the first embodiment, the magnitude of the voltage applied to the nano-carbon laminated film 50 of the IR+R pixel 63IR and the number of laminated layers of graphene included in the nano-carbon laminated film 50 are adjusted. This extends a dynamic range.

In addition, also in the present embodiment, as in the first embodiment, a function of removing a noise signal ΔE resulting from a dark current from the red pixel 39R, the blue pixel 39B, and the green pixel 39G (noise cancelling function) can be imparted. Specifically, also in the present embodiment, the red pixel 39R, the green pixel 39G, and the blue pixel 39B allow light in the infrared region as well as light in the respective color regions to pass through the color filter layers. Hence, the red pixel 39R, the green pixel 39G, and the blue pixel 39B obtain the signal component in the infrared region as well as the signal components according to the light in the respective color regions, and the noise component ΔE is added to these signal components.

On the other hand, a wavelength region of transmissible light in the IR+R pixel 63IR is adjusted by adjusting the voltage applied to the nano-carbon laminated film 50 so as to obtain only the signal component in the infrared region in addition to the noise component ΔE.

Hence, the infrared component and the noise component ΔE obtained in the IR+R pixel 63IR for which the applied voltage is adjusted are removed from sums of the signal components in the respective color regions, the infrared component, and the noise component ΔE obtained in the visible light pixels. Thereby noise can be cancelled.

[2-2 Case where Green Filter is Used for IR Pixel]

Description will next be made of a case where a green filter is used as the color filter layer 62. In this case, the nano-carbon laminated film 50 is formed so as not to transmit light when voltage is not applied between the first electrode 51 and the second electrode 53, and so as to transmit light up to the wavelength region of green when a predetermined voltage (for example 30V) is applied between the first electrode 51 and the second electrode 53.

In the following description, the pixel provided with the nano-carbon laminated film 50 will be described as an IR +G pixel 63IR.

FIG. 20B is a diagram showing a layout of a light receiving surface of the solid-state imaging element 61 when the color filter layer 62 is a green filter. In this case, as shown in FIG. 20B, four pixels, that is, a red pixel 39R, a blue pixel 39B, a green pixel 39G, and the IR+G (green) pixel 63IR disposed so as to be adjacent to each other in two horizontal rows and two vertical columns form one unit pixel. The red pixel 39R obtains a signal component according to light in the red region. The green pixel 39G obtains a signal component according to light in the green region. The blue pixel 39B obtains a signal component according to light in the blue region. The IR+G pixel 63IR obtains signal components according to light in the infrared region and the green region only when voltage is applied to the nano-carbon laminated film 50.

According to the solid-state imaging element 61 according to the present embodiment, when the voltage applied to the nano-carbon laminated film 50 is set at 30 V, for example, the IR+G pixel 63IR obtains the signal component according to the light in the infrared region and the signal component according to the light in the green region as a visible light component as a result of the application of the voltage. Thus, the provision of the IR pixel does not reduce visible light pixels.

Consequently, there is no problem of decrease in resolution due to the provision of the IR pixel, and there is no problem of decrease in resolution in a dark scene during a nighttime or the like because transmittance can be changed by the application of the voltage. In addition, because the IR+G pixel 63IR produces the effects of both of an IR pixel and a green pixel, imaging in a range from the visible light region to the infrared light region can be performed at a high resolution even during a nighttime or the like.

Further, as shown in FIG. 20B, because the ratio of the green pixels 39G provided in one unit pixel is one half of the whole of the one unit pixel, the resolution of green can improve apparent resolution. This is because the spectral sensitivity of a human eye has a peak around green.

In addition, also in the solid-state imaging element 61 according to the present embodiment, as in the first embodiment, a dynamic range is extended by adjusting the magnitude of the voltage applied to the nano-carbon laminated film 50 of the IR+G pixel 63IR and the film thickness of the nano-carbon laminated film 50. In addition, also in the present embodiment, as in the case where the color filter layer 62 is a red filter, a function of removing a noise signal ΔE resulting from a dark current from the red pixel 39R, the blue pixel 39B, and the green pixel 39G (noise cancelling function) can be imparted.

[2-3 Case where White Filter is Used for IR Pixel]

Description will next be made of a case where a white filter is used as the color filter layer 62. In this case, the nano-carbon laminated film 50 is formed so as not to transmit light when voltage is not applied between the first electrode 51 and the second electrode 53, and so as to transmit white light (that is, all wavelengths) when a predetermined voltage (for example 10V) is applied between the first electrode 51 and the second electrode 53.

In the following description, the pixel provided with the nano-carbon laminated film 50 will be described as an IR+W pixel 63IR.

FIG. 20C is a diagram showing a layout of a light receiving surface of the solid-state imaging element 61 when the color filter layer 62 is a white filter. In this case, as shown in FIG. 20C, four pixels, that is, a red pixel 39R, a blue pixel 39B, a green pixel 39G, and the IR+W pixel 63IR disposed so as to be adjacent to each other in two horizontal rows and two vertical columns form one unit pixel. The red pixel 39R obtains a signal component according to light in the red region. The green pixel 39G obtains a signal component according to light in the green region. The blue pixel 39B obtains a signal component according to light in the blue region. The IR+W pixel 63IR obtains signal components according to the infrared region and white light only when voltage is applied to the nano-carbon laminated film 50. The solid-state imaging element 61 according to the present embodiment can extend the region of transmissible wavelengths of the nano-carbon laminated film 50 to all wavelengths when the voltage applied to the nano-carbon laminated film 50 is set at 10 V, for example. Therefore, in the solid-state imaging element 61 according to the present embodiment, the signal components read out from the visible light pixels are the signal component in the infrared region, the signal components in the visible light region, and a noise component ΔE. In addition, the signal components read out from the IR+W pixel 63IR are the signal component in the infrared region, the signal component of the white light, and the noise component ΔE when the voltage applied to the nano-carbon laminated film 50 is on. When the applied voltage is off, on the other hand, only the noise signal ΔE is read out from the IR+W pixel 63IR.

According to the solid-state imaging element 61 according to the present embodiment as described above, the IR+W pixel 63IR obtains the signal component according to the light in the infrared region and the signal component according to the white light as a result of the application of the voltage. Thereby, the solid-state imaging element 61 according to the present embodiment eliminates a problem of decrease in resolution due to the provision of the IR pixel, and eliminates a problem of decrease in resolution in a dark scene during a nighttime or the like because transmittance can be changed by the application of the voltage. In addition, because the IR+W pixel 63IR produces the effects of both of an IR pixel and a white pixel, imaging in a range from the visible light region to the near-infrared region can be performed at a high resolution even during a nighttime or the like.

In addition, also in the solid-state imaging element 61 according to the present embodiment, as in the first embodiment, a dynamic range is extended by adjusting the magnitude of the voltage applied to the nano-carbon laminated film 50 and the film thickness of graphene forming the nano-carbon laminated film 50.

In addition, also in the present embodiment, as in the case where a red filter is used as the color filter layer 62, a function of removing a noise signal resulting from a dark current from the red pixel 39R, the blue pixel 39B, and the green pixel 39G (noise cancelling function) can be imparted.

The sectional view of the solid-state imaging element 61 which sectional view is used in the present embodiment is not limited to FIG. 19, but materials, the order of lamination, and the like can be set variously so as to achieve desired functions and performance.

In addition, the solid-state imaging element 61 according to the present embodiment may have an IR cutoff filter over the pixels other than the IR+R (G, or W) pixel 63IR as in the first modification. In addition, the nano-carbon laminated film may be provided over the entire effective pixel region when the transmittance of the nano-carbon laminated film provided to each pixel can be controlled in pixel units.

Further, the nano-carbon laminated film 50 may be formed by using similar materials to those of the nano-carbon laminated film 45 shown in FIG. 10. In addition, the nano-carbon laminated film 50 may have a constitution in which nano-carbon layers forming first electrodes and second electrodes and dielectric layers are alternately laminated as in the nano-carbon laminated film 55 shown in FIG. 16. In this case, the number of laminated nano-carbon layers can also be changed according to a purpose. In addition, materials for the nano-carbon layers are not limited to the present embodiment as long as the materials can exhibit similar characteristics to those of graphene.

In addition, the solid-state imaging element 61 according to the present embodiment uses a device having Si-base photoelectric conversion sections PD as sensor parts, but is not limited to the Si-base device. For example, provisions can be made variously for organic photoelectric conversion films as photoelectric conversion sections PD, bolometer type devices, and the like.

### 3. Third Embodiment: Example of Solid-State Imaging Element

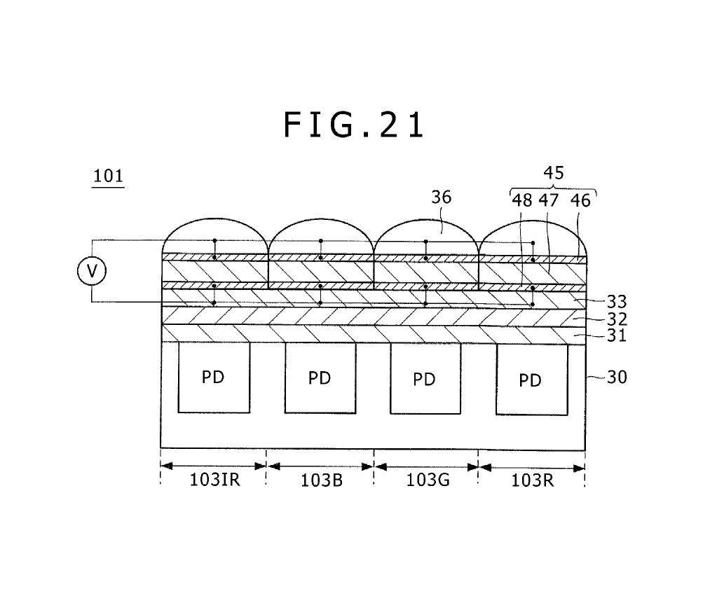

Description will next be made of a solid-state imaging element according to a third embodiment of the present disclosure. FIG. 21 is a schematic sectional view of four pixels of the solid-state imaging element 101 according to the present embodiment. The solid-state imaging element 101 according to the example of the present embodiment has a constitution in which nano-carbon laminated films 45 according to the second modification are formed individually over an entire pixel region and no color filter is provided. In FIG. 21, parts corresponding to those of FIG. 4 are identified by the same reference numerals, and repeated description thereof will be omitted.

In the following description, suppose that a pixel provided with the nano-carbon laminated film 45 transmitting light in the red wavelength region is a red pixel 103R, and that a pixel provided with the nano-carbon laminated film 45 transmitting light in the green wavelength region is a green pixel 103G. Similarly, the following description will be made supposing that a pixel provided with the nano-carbon laminated film 45 transmitting light in the blue wavelength region is a blue pixel 103B, and that a pixel provided with the nano-carbon laminated film 45 transmitting light from the near-infrared region to the terahertz region is an IR pixel 103IR.

The nano-carbon laminated films 45 are similar to the nano-carbon laminated film 45 described with reference to FIG. 10. Specifically, the nano-carbon laminated films 45 include a first electrode 46, a dielectric layer 47, and a second electrode 48.

A first electrode, a dielectric layer, and a second electrode similar to the first electrode 46, the second electrode 48, and the dielectric layer 47 of the nano-carbon laminated film 45 described with reference to FIG. 10 are applied as the first electrode 46, the second electrode 48, and the dielectric layer 47. Incidentally, the dielectric layer 47 is formed of a normal dielectric constant material or a high dielectric constant material as described above.

The dielectric layer 47 is disposed so as to be sandwiched between the first electrode 46 and the second electrode 48, and is formed of a material having a desired dielectric constant which material is selected for each pixel from among the materials shown in Table 1 above.

The dielectric layers 47 in the visible light pixels are formed by using a high dielectric constant material. The dielectric layer 47 in the IR pixel 103IR is formed by using a normal dielectric constant material. In addition, the dielectric layers 47 in the visible light pixels are formed by using high dielectric constant materials whose relative dielectric constant increases in order of decreasing target light reception wavelength in the pixels. For example, the dielectric layer 47 in the IR pixel is formed by using SiO₂, the dielectric layer 47 in the red pixel 103R is formed by using HfO₂, the dielectric layer 47 in the green pixel 103G is formed by using ZrO₂, and the dielectric layer 47 in the blue pixel 103B is formed by using PLZT.

Incidentally, in the present embodiment, the dielectric layers 47 are formed by the different materials selected for the respective pixels, but may also be formed by using a same material. In this case, for example, the dielectric layers 47 in the green pixel 103G and the blue pixel 103B are formed of a same material, and only the first electrode and the second electrode of the blue pixel 103B are formed by graphene doped with an impurity. This can expand a wavelength region of transmissible light in the blue pixel 103B, so that a signal according to light in the wavelength region of blue can be obtained even when the same material as that of the dielectric layer 47 in the green pixel 103G is used.

In addition, in the present embodiment, four pixels, that is, the red pixel 103R, the green pixel 103G, the blue pixel 103B, and the IR pixel 103IR disposed so as to be adjacent to each other in two horizontal rows and two vertical columns form one unit pixel. While the above four pixels form one unit pixel in the present embodiment, the red pixel 103R, the blue pixel 103B, or the green pixel 103G may be used in place of the IR pixel 103IR. Further, the number of laminated nano-carbon layers (graphene) forming each nano-carbon laminated film 45 is determined so as not to transmit light when no voltage is applied, and so as to transmit light of target wavelengths when a predetermined voltage is applied. In the solid-state imaging device having the constitution as described above, all of the pixels do not transmit light but obtain only the noise signal ΔE when voltage is not applied to the nano-carbon laminated films 45. On the other hand, when voltage is applied to the nano-carbon laminated films 45, the pixels obtain respective signals as follows.

For example, the red pixel 103R obtains a signal component according to light in the infrared region and the red region and the noise component ΔE. Similarly, the green pixel 103G obtains a signal component according to light from the infrared region to the green region and the noise component ΔE. In addition, the blue pixel 103B obtains a signal component according to light from the infrared region to the blue region and the noise component ΔE. Further, the IR pixel 103IR obtains a signal component according to light in the infrared region and the noise component ΔE.

As described above, the solid-state imaging element 101 according to the present embodiment has the constitution in which the nano-carbon laminated film 45 is provided for each pixel and a wavelength region of transmissible light and transmittance can be modulated by selecting dielectric layers 47 having desired dielectric constants. Therefore, even the constitution without a color filter layer provided thereto can obtain the signal components of the respective colors using the signal components obtained in the respective pixels as follows.

The signal component in the red region of the red pixel 103R can be obtained by subtracting the whole of the signal component obtained in the IR pixel 103IR from the whole of the signal component obtained in the red pixel 103R when voltage is applied to the nano-carbon laminated films 45.

In addition, in the green pixel 103G, the signal component in the green region can be obtained by subtracting the whole of the signal component of the red pixel 103R from the whole of the signal component of the green pixel 103G when voltage is applied to the nano-carbon laminated films 45.

In addition, in the blue pixel 103B, the signal component in the blue region can be obtained by subtracting the whole of the signal component of the green pixel 103G from the whole of the signal component of the blue pixel 103B when voltage is applied to the nano-carbon laminated films 45.

It is to be noted that both of the signal component in the infrared region and the noise component ΔE are removed from the signal components in the respective color regions which signal components are obtained as described above, and that only the signal components whose noise is cancelled out are obtained.

In addition, in the IR pixel 103IR, the signal component in the infrared region can be obtained by subtracting the noise component ΔE of the red, green, or blue pixel when the applied voltage is off from the whole of the signal component of the IR pixel.

As described above, according to the solid-state imaging element 101 according to the present embodiment, the nano-carbon laminated film 45 shown in FIG. 10 is provided for each pixel, whereby transmission wavelengths of light incident on each pixel can be separated even when color filter layers are not provided. Thus, as compared with a constitution provided with color filter layers, there is no loss of incident light, and the device can be reduced in height (reduced in thickness). In addition, also in the solid-state imaging element 101 according to the present embodiment, as in the second embodiment, a dynamic range is extended in each pixel by adjusting the magnitude of the voltage applied to the nano-carbon laminated film 45 of each pixel and the film thickness of the nano-carbon laminated film 45.

In addition, also in the present embodiment, as described above, a function of removing a noise signal ΔE resulting from a dark current from the red pixel 103R, the blue pixel 103B, and the green pixel 103G (noise cancelling function) can be imparted.

The solid-state imaging element 101 used in the present embodiment is not limited to the constitution shown in the sectional view of FIG. 21, but materials, the order of lamination, and the like can be set variously so as to achieve desired functions and performance. It suffices for the nano-carbon laminated film 45 to be present between a photoelectric conversion section PD and a condensing lens 36. For example, the nano-carbon laminated film 45 may be provided between a planarizing film 33 and a substrate 30.

In addition, also in the present embodiment, as in the second embodiment, when the red pixel 103R is provided in place of the IR pixel 103IR, for example, visible light pixels are not reduced, and therefore a problem of decrease in resolution is eliminated. In addition, an amount of signal degradation of the green pixel 103G can be compensated by using a high-frequency component of a high-resolution signal in the red region which signal is obtained in the red pixel 103R. That is, a blurred color can be corrected by combining the high-frequency component of a sharp color.

In addition, when the green pixel 103G is provided in place of the IR pixel 103IR, for example, visible light pixels are not reduced, and therefore a problem of decrease in resolution is eliminated. In addition, because the ratio of the green pixels 103G provided in one unit pixel is one half of the whole of the one unit pixel, the resolution of green can improve apparent resolution.

In addition, the nano-carbon laminated films 45 of the solid-state imaging element 101 according to the present embodiment may have a constitution in which graphene doped with an impurity is provided as the first electrode and the second electrode as in the nano-carbon laminated film 50 shown in FIG. 15. Further, the nano-carbon laminated films 45 may have a constitution in which nano-carbon layers forming first electrodes and second electrodes and dielectric layers are alternately laminated as in the nano-carbon laminated film 55 shown in FIG. 16.

In addition, the dielectric layers 47 of the nano-carbon laminated films 45 may be formed of a normal dielectric constant material in the entire pixel region of the solid-state imaging element 101 according to the present embodiment. In this case, all pixels are formed as the IR pixel 103IR. Thus, in imaging in a dark scene during a nighttime or inside a room, for example, sensitivity is improved, and a sufficient signal amount can be obtained. In addition, a color filter layer may be formed under the nano-carbon laminated films 45.

In addition, materials for the nano-carbon layers are not limited to the present embodiment as long as the materials can exhibit similar characteristics to those of graphene.

In addition, the solid-state imaging element 101 according to the present embodiment uses a device having Si-base photoelectric conversion sections PD as sensor parts, but is not limited to the Si-base device. For example, provisions can be made variously for organic photoelectric conversion films as photoelectric conversion sections PD, bolometer type devices, and the like.

Further, while the foregoing first to third embodiments have been described using a CMOS type solid-state imaging element, nano-carbon laminated films according to embodiments of the present disclosure are applicable also to CCD type solid-state imaging elements.

The nano-carbon laminated films used in the solid-state imaging elements in the foregoing first to third embodiments can be used as a light control element in a shutter device of an electronic apparatus, for example. An example in which a nano-carbon laminated film is used in a shutter device will be shown in the following.

### 4. Fourth Embodiment

### Example of Imaging Device Having Shutter Device

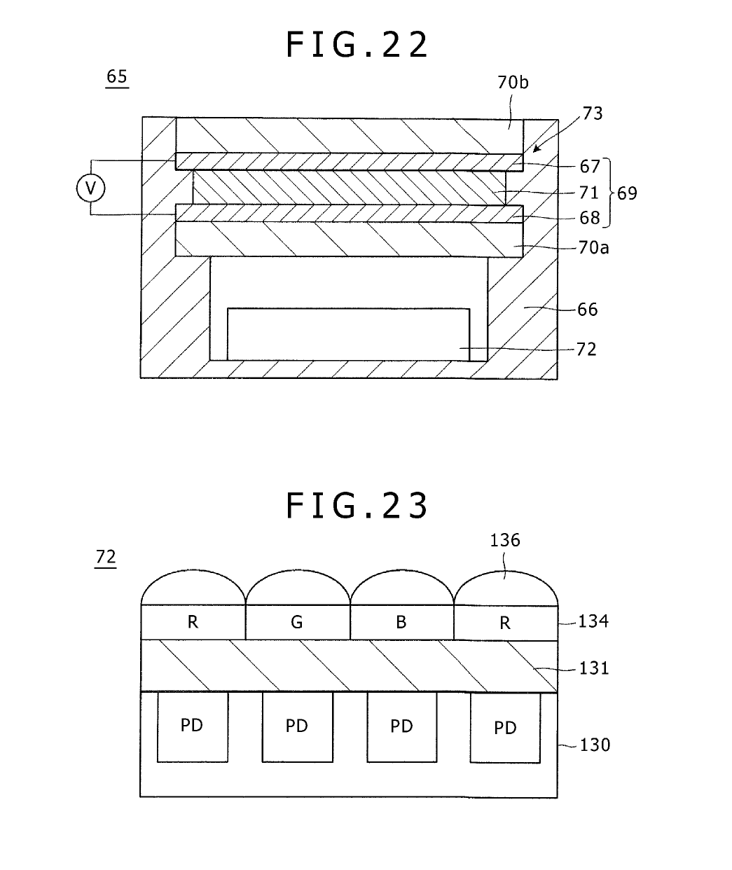

An imaging device according to a fourth embodiment of the present disclosure will next be described. FIG. 22 is a schematic constitutional diagram of an imaging device 65 according to the present embodiment. The imaging device 65 according to the present embodiment is an example in which a shutter device 73 is provided on the light incidence side of a solid-state imaging element 72 mounted within a resin package 66.

The imaging device 65 according to the present embodiment includes the solid-state imaging element 72, the resin package 66 sealing the solid-state imaging element 72, seal glasses 70a and 70b, and a shutter device 73. The resin package 66 is formed of an electrically insulated material, and is formed by a shallow-bottom casing having a bottom part on one side and having an opening on another side. The solid-state imaging element 72 is mounted on the bottom surface of the resin package 66. The seal glasses 70a and 70b and the shutter device 73 are formed on the opening end side of the resin package 66.

FIG. 23 is a sectional constitutional view showing in enlarged dimension the solid-state imaging element 72. As shown in FIG. 23, the solid-state imaging element 72 includes a substrate 130 having a plurality of photoelectric conversion sections PD formed therein, an interlayer insulating film 131, color filter layers 134, and a condensing lens 136.

The interlayer insulating film 131 is formed of SiO₂, for example. Wiring not shown in the figures is provided within the interlayer insulating film 131 as required. The color filter layers 134 are provided on the planarized interlayer insulating film 131. The respective color filter layers 134 of R (red), G (green), and B (blue) are formed in a Bayer arrangement, for example. In addition, color filter layers transmitting a same color in all pixels may be used as the color filter layers 134. Various combinations of colors can be selected in the color filter layers 134 according to specifications of the color filter layers 134. The condensing lens 136 is provided on the color filter layers 134, and is formed in a convex shape for each pixel. Light condensed by the condensing lens 136 is made incident on the photoelectric conversion section PD of each pixel efficiently. The solid-state imaging element 72 used in the present embodiment is a commonly used solid-state imaging element, and is not limited to the example shown in FIG. 23.

In the solid-state imaging element 72 having such a constitution, connection wiring not shown in the figures is connected within the resin package 66. Electric connection to the outside of the resin package 66 can be established via the connection wiring.

The seal glasses 70a and 70b are formed by a transparent member, and are formed so as to seal the opening part of the resin package 66 and thus maintain the inside of the resin package 66 in an airtight state. The shutter device 73 is formed in a region sandwiched between the two seal glasses 70a and 70b.

### [Shutter Device]

The shutter device 73 will next be described. The shutter device 73 according to the present embodiment includes a nano-carbon laminated film 69 having a first electrode 67, a dielectric layer 71, and a second electrode 68 and a voltage power supply V serving as a voltage applying section. A voltage is applied between the first electrode 67 and the second electrode 68 to modulate the transmittance of light.

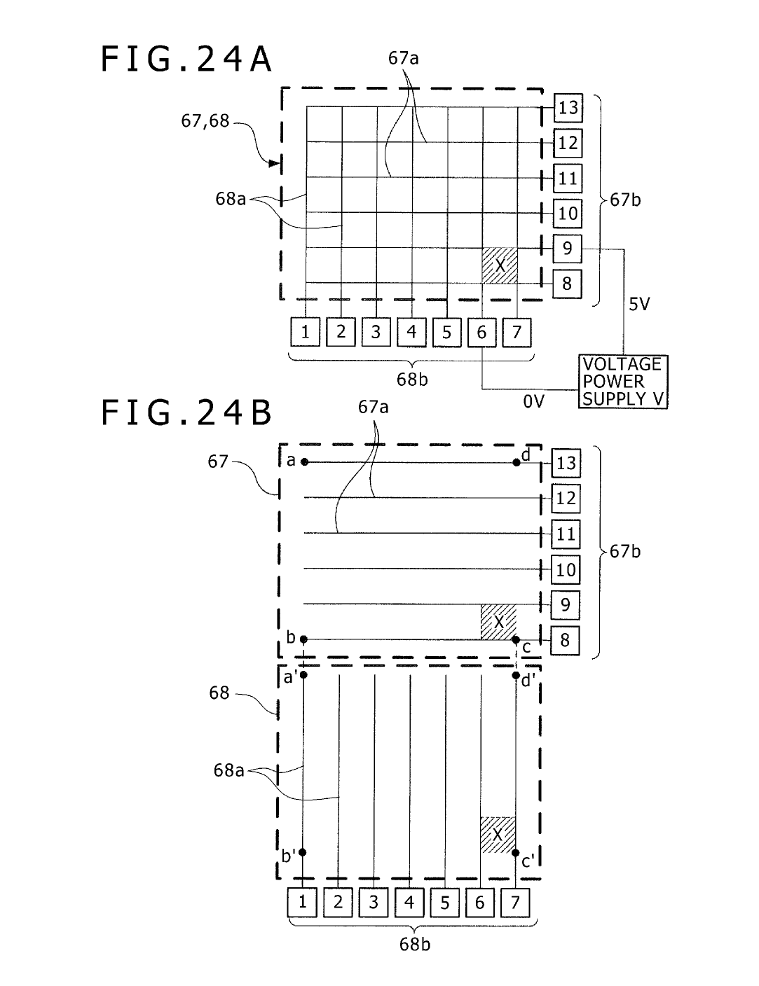

The dielectric layer 71 is formed of alumina oxide (Al₂O₃), for example, and is formed so as to be sandwiched between the first electrode 67 and the second electrode 68. Incidentally, the dielectric layer 71 is not limited to this, and may be formed of another dielectric constant material (a normal dielectric constant material or a high dielectric constant material) as described above. The first electrode 67 and the second electrode 68 are each formed by one nano-carbon layer or a plurality of nano-carbon layers. In the present embodiment, graphene is used as the nano-carbon layers forming the first electrode 67 and the second electrode 68. A plurality of pieces of wiring to be described later are provided in respective planes of the first electrode 67 and the second electrode 68 which planes correspond to an effective pixel region of the solid-state imaging element 72. The shutter device 73 allows voltage to be applied to the dielectric layer 71 via these pieces of wiring. FIG. 24A is a plan constitutional view of the first electrode 67 and the second electrode 68 in the shutter device 73 according to the example of the present embodiment when the first electrode 67 and the second electrode 68 are superposed on each other. FIG. 24B is a plan constitutional view separately showing the first electrode 67 and the second electrode 68 in the shutter device 73 according to the example of the present embodiment as an upper part and a lower part.

As shown in FIGS. 24A and 24B, a plurality of pieces of first wiring 67a for voltage application are disposed in the first electrode 67 so as to extend in one direction at pixel pitch intervals of the solid-state imaging element 72. Pad sections 67b are provided at one end of each piece of first wiring 67a. The pad sections 67b are connected to the voltage power supply V. A voltage is selectively supplied from the voltage power supply V to a desired pad section 67b, whereby the voltage is applied to the piece of first wiring 67a connected to the pad section 67b.

A plurality of pieces of second wiring 68a for voltage application are disposed in the second electrode 68 so as to extend in a direction orthogonal to the first wiring 67a at pixel pitch intervals of the solid-state imaging element 72. Pad sections 68b are provided at one end of each piece of second wiring 68a. The pad sections 68b are connected to the voltage power supply V. A voltage is selectively supplied from the voltage power supply V to a desired pad section 68b, whereby the voltage is applied to the piece of second wiring 68a connected to the pad section 68b.

In FIGS. 24A and 24B, the pad sections 67b and 68b provided to the respective pieces of wiring are numbered to clarify the positions of the pad sections 67b and 68b. The first electrode 67 and the second electrode 68 are laminated such that points a and a′, points b and b′, points c and c′, and points d and d′ shown in FIG. 24B coincide with each other.

In such a shutter device 73, the voltage power supply V is connected to the first wiring 67a and the second wiring 68a so that a voltage can be applied between desired pieces of wiring. Thus, when a voltage is applied to the first wiring 67a and the second wiring 68a, the transmittance of light and a wavelength region of transmissible light can be modulated for each pixel that corresponds to the wiring to which the voltage is applied. The operation of the shutter device 73 will be described below in detail.

In the shutter device 73, when a voltage of 5 [v] is desired to be applied to a region X in FIGS. 24A and 24B, for example, a voltage of 5 [v] is applied to the ninth pad section 67b of the first electrode 67, and a voltage of 0 [v] is applied to the sixth pad section 68b of the second electrode 68. Thereby the voltage of 5 [v] can be applied to the region X, in which region these pad sections 67b and 68b intersect each other. Then, the application of the voltage to the region X changes the transmittance of the region X.

Hence, the shutter device 73 according to the present embodiment can change transmittance in pixel units by applying a voltage between desired pieces of wiring when the transmittance needs to be adjusted locally at a time of imaging. Thus, when transmissible wavelengths in the shutter device 73 at the time of voltage application are light in the infrared region, the shutter device 73 can be used as a shutter for the infrared region.

A commonly used mechanical shutter for a camera is located on the outside of a large-diameter lens, and because of the presence of the device, the shutter part is costly. One atomic layer of the graphene layers used in the present embodiment is 0.3 nm thick, and thus the graphene layers used in the present embodiment are about 10 nm thick even when laminated. Therefore, as compared with mechanical shutters, the shutter device 73 according to the present embodiment can be miniaturized.

Further, the imaging device 65 according to the present embodiment can adjust the transmittance of light and a wavelength region of transmissible light in each pixel of the effective pixel region. Therefore, underexposure can be prevented by applying a voltage to a dark part and thus adjusting the transmittance of light at one time of imaging. In addition, overexposure can be prevented even at a bright location of a mountain covered with snow or the like.

In addition, also in the shutter device 73 according to the present embodiment, as in the first to third embodiments, a dynamic range is extended by adjusting the magnitude of the voltage applied to the nano-carbon laminated film 69 and the film thickness of the nano-carbon layers (graphene).

In addition, the imaging device 65 according to the present embodiment can extend the dynamic range also by a method of voltage application of signal processing using fast reaction (GHz) or the like. An example of the signal processing method using fast reaction (GHz), for example, will be described in the following.

For example, the nano-carbon laminated film 69 of the shutter device 73 according to the present embodiment can modulate the wavelength region of transmissible light according to the magnitude of direct-current application voltage. In addition, when pulse application of voltage is performed, the transmittance of light can be modulated with transmitted wavelengths of light fixed.

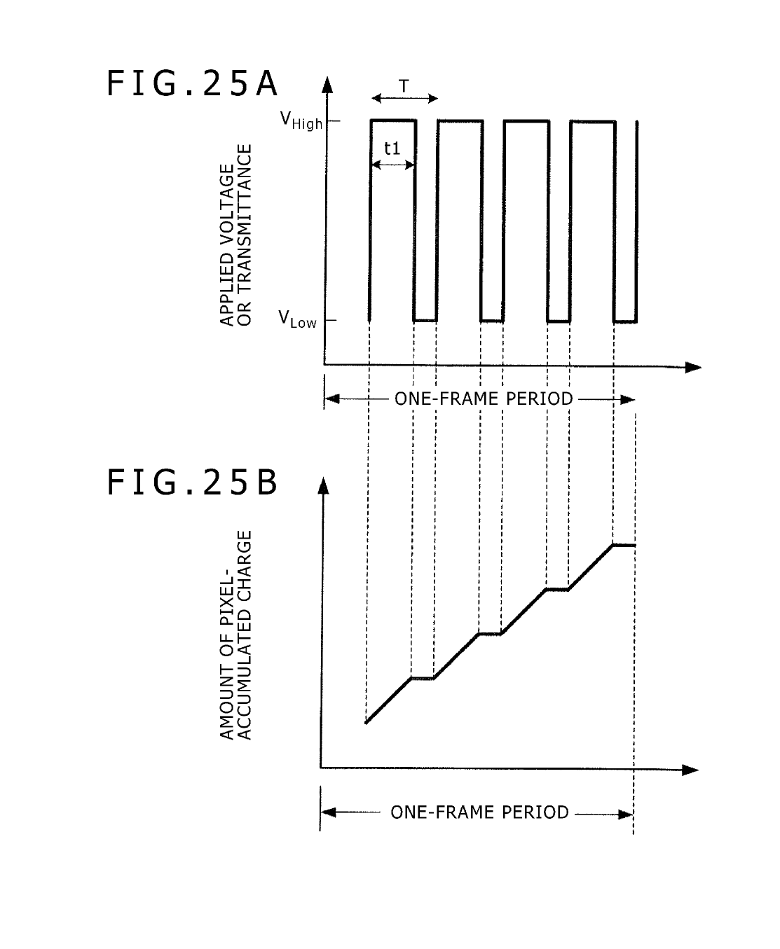

FIG. 25A is a diagram showing relation of the magnitude of voltage and the transmittance of light to one frame period in a case where the shutter device 73 according to the present embodiment is made to perform pulse application of the voltage having a pulse period T and a V_{High} period t1. FIG. 25B is a diagram showing relation of an amount of pixel-accumulated charge to the one frame period in a case where the pulse voltage shown in FIG. 25A is applied to the shutter device 73.

As shown in FIG. 25A, an axis of ordinates of the graph indicates the magnitude of the applied voltage or the transmittance of light, and an axis of abscissas of the graph indicates the time of the one frame period from the opening of the shutter of the shutter device 73 to the closing of the shutter. In addition, suppose that arbitrary voltages applied to the shutter device 73 according to the present embodiment are V_{High} and V_{Low}, and that a time of application of both of V_{High} and V_{Low} together is the pulse period T and a time of application of V_{High} is the pulse width t1. At this time, a duty ratio D is D=t1/T.

As shown in the graph of FIG. 25A, in the V_{High} period, the transmittance is higher than in the V_{Low} period, and thus a large amount of signal charge is obtained. Hence, as shown in FIG. 25B, the amount of signal charge obtained in the V_{High} period is accumulated at a faster speed than in the V_{Low} period. In the V_{Low} period, on the other hand, the transmittance is lower than in the V_{High} period, and thus a small amount of signal charge is obtained. Hence, as shown in FIG. 25B, the amount of signal charge obtained in the V_{Low} period is accumulated at a slow speed. An amount of accumulated signal obtained in one frame period in the case where the pulse application of voltage is performed is obtained by adding up amounts of accumulated signal in the V_{High} period and the V_{Low} period. Hence, when the time during which the voltage is applied is changed in each of the V_{High} period and the V_{Low} period, the duty ratio D of the rectangular wave can be changed. In addition, the present embodiment can also change integrated transmittance by changing the duty ratio D. That is, the transmittance of light can be changed, and signal charges corresponding to V_{High} and V_{Low}, respectively, are obtained, so that amounts of information for both of a bright part and a dark part can be obtained at a time of imaging.

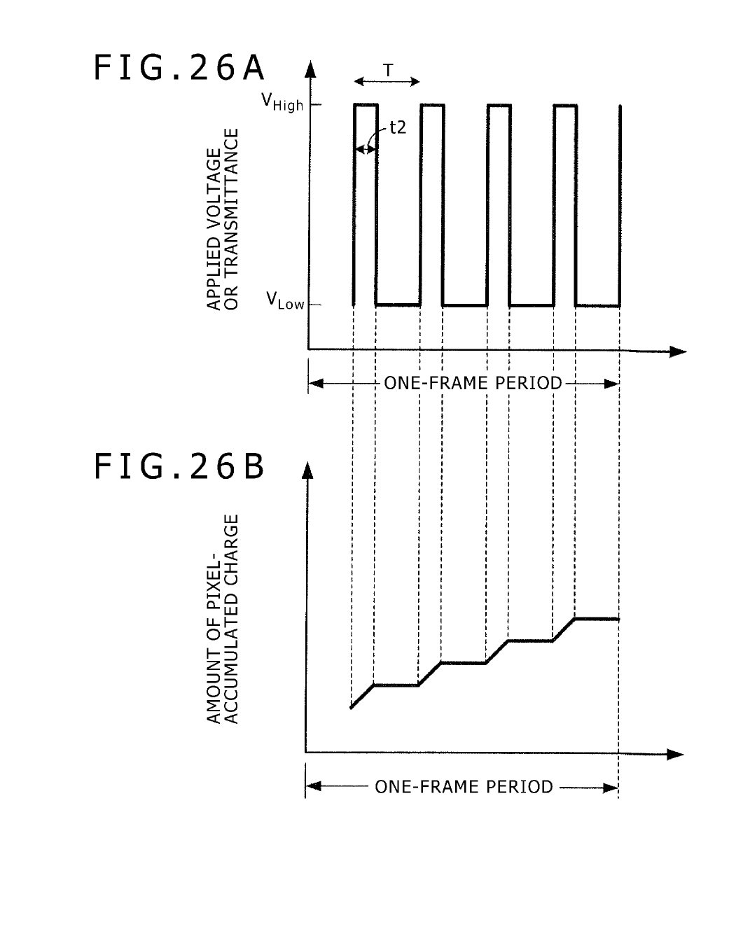

Description will next be made of an example in which the duty ratio D of the rectangular wave is changed by varying each of the times of application of the voltages. FIG. 26A is a diagram showing relation of the magnitude of voltage and the transmittance of light to one frame period in a case where the shutter device 73 is made to perform pulse application of the voltage having the pulse period T and a V_{High} period t2 (<t1). FIG. 26B is a diagram showing relation of an amount of pixel-accumulated charge to the one frame period in a case where the pulse voltage shown in FIG. 26A is applied to the shutter device 73.

In FIG. 26A, suppose that a time of application of both of arbitrary voltages V_{High} and V_{Low} together which voltages are applied to the shutter device 73 according to the present embodiment is the pulse period T, and that a time of application of V_{High} is a pulse width t2.

As is understood from FIG. 25B and FIG. 26B, a slope in the graph is made gentler by changing the V_{High} period from t1 to t2 (<t1). This is because the speed of accumulation of the amount of accumulated signal obtained by adding up the amounts of accumulated signal in the V_{High} period and the V_{Low} period becomes slower as a whole due to a decreased ratio of the V_{High} period in the pulse period T.

Hence, a period until an amount of saturation charge is reached can be extended by performing pulse application of voltage to the shutter device 73 according to the present embodiment and changing the duty ratio of the rectangular wave. Therefore a dynamic range can be extended.

In addition, such a shutter device 73 is formed with graphene used for the electrodes, and thereby optical transparency is improved as compared with a case where indium tin oxide (ITO) is used for the electrodes.

While description has been made of an example in which the imaging device 65 according to the foregoing fourth embodiment has the shutter device 73 disposed on the light incidence side of the solid-state imaging element 72 mounted within the resin package 66, the sectional view of the imaging device 65 is not limited to FIG. 22. In addition, an ordinary solid-state imaging element may be used as the solid-state imaging element 72 in the present embodiment, and the constitution of the solid-state imaging element is not limited in the present embodiment. In addition, the structure of the shutter device 73 used in the present embodiment is not limited to FIG. 22. Not only the form as shown in FIG. 24A but also various settings are possible as long as the transmittance of light can be modulated. In addition, as a substrate provided with the shutter device 73, a Qz substrate, for example, can be used, and also a thin film such as a PET film or the like can be used. When the shutter device 73 is formed on a PET film, the shutter device as a whole is formed like a flexible sheet, and the shutter itself can be handled in the form of the sheet, so that the shutter device can be miniaturized.

The shutter device 73 used in the present embodiment has the first wiring 67a and the second wiring 68a connected to the pad sections 67b and 68b, respectively, and adjusts transmittance locally by selecting the pad sections 67b and 68b to which to apply a voltage. However, the shutter device 73 usable in the present embodiment is not limited to this. For example, a selecting circuit may be configured separately, and the selecting circuit may be used to apply a voltage selectively to desired pieces of first wiring 67a and second wiring 68b.

While description has been made of an example in which the imaging device 65 according to the foregoing fourth embodiment has the shutter device 73 disposed over the light incidence side of the solid-state imaging element 72 with a space interposed between the shutter device 73 and the light incidence side of the solid-state imaging element 72, the transmittance of light can be modulated also in a case where the shutter device 73 and the solid-state imaging element 72 are brought into close contact with each other. In this case, the transmittance of light in each pixel of the effective pixel region can be adjusted accurately. An example of an imaging device in which the shutter device 73 and the solid-state imaging element 72 are brought into close contact with each other will be cited in the following.

### 5. Fifth Embodiment

### Example of Imaging Device Having Shutter Device

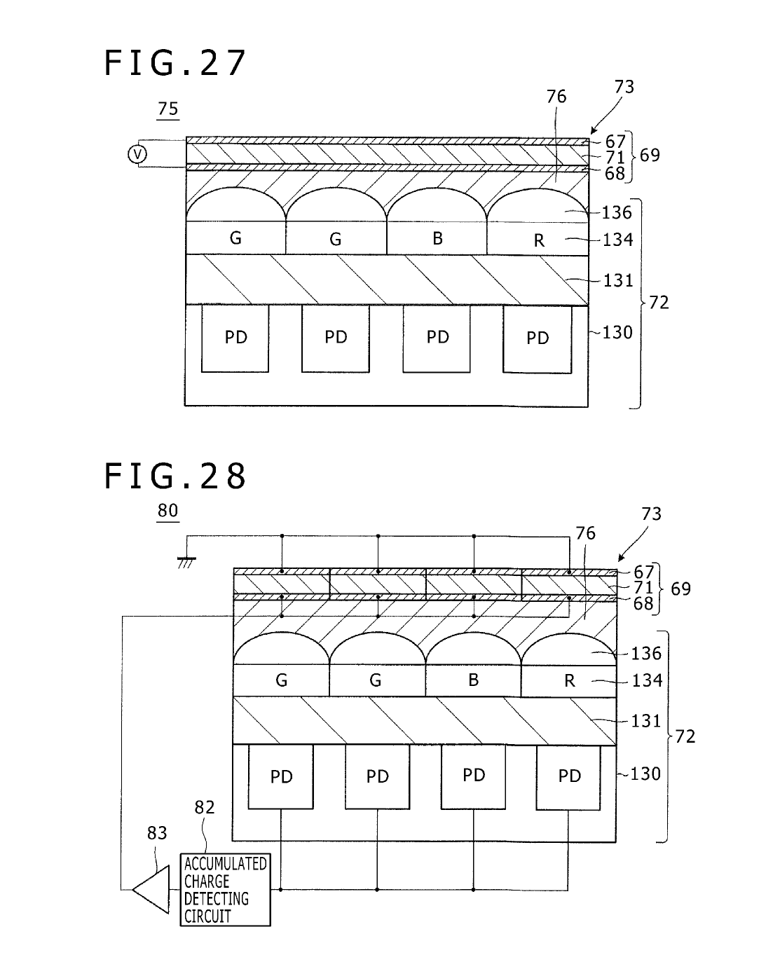

FIG. 27 is a sectional constitutional view of an imaging device 75 having a shutter device according to an example of a present embodiment. The imaging device 75 according to the present embodiment is an example having the shutter device 73 directly on the solid-state imaging element 72 used in the fourth embodiment. That is, a molded resin (not shown) provided on the outside of the solid-state imaging element 72 and the shutter device 73 are brought into close contact and integrated with each other. In FIG. 27, parts corresponding to those of FIG. 22 are identified by the same reference numerals, and repeated description thereof will be omitted.

As shown in FIG. 27, the imaging device 75 according to the present embodiment has the shutter device 73 formed over a condensing lens 136 with a planarizing film 76 interposed between the shutter device 73 and the condensing lens 136. The shutter device 73 includes a first electrode 67, a dielectric layer 71, and a second electrode 68. The constitution of such a shutter device 73 is similar to that of the shutter device 73 according to the fourth embodiment, and materials similar to those of the shutter device 73 according to the fourth embodiment can be used.

Also in the present embodiment, wiring for voltage application is arranged for each effective pixel at a pixel pitch in the first electrode 67 and the second electrode 68, and the transmittance of light and a wavelength region of transmissible light can be modulated for each pixel by applying a voltage to each pixel.

In the fourth embodiment, as described above, a method of applying a voltage to pad sections provided for respective wiring parts is used as an example of applying a desired application voltage to the first electrode 67 and the second electrode 68 to modulate the transmittance of light and the wavelength region of transmissible light. Similarly, also in the present embodiment, a method of applying a voltage to pad sections provided for respective wiring parts or a method of selectively applying a voltage to necessary pixels using a selecting circuit is cited.

In the imaging device 75 according to the present embodiment, the pad sections 67b and 68b shown in FIG. 24A and the selecting circuit are provided to the substrate 130 forming the solid-state imaging element 72, and voltage is applied to each pixel.

When the operation of the shutter device and the operation of the solid-state imaging element are synchronized with each other, voltage applied to the shutter device can be varied according to a signal amount accumulated in the photoelectric conversion sections PD of the solid-state imaging element. Description in the following will be made of an example in which the operation of the shutter device and the operation of the solid-state imaging element are synchronized with each other.

### 6. Sixth Embodiment

### Example of Imaging Device Having Shutter Device

FIG. 28 is a sectional constitutional view of an imaging element according to a sixth embodiment of the present disclosure. In FIG. 28, parts corresponding to those of FIG. 27 are identified by the same reference numerals, and repeated description thereof will be omitted.

As shown in FIG. 28, an accumulated charge detecting circuit 82 for detecting a signal charge generated and accumulated in photoelectric conversion sections PD is connected to a second electrode 68 in a shutter device 73 via an amplifying circuit 83. The signal charge generated and accumulated in the photoelectric conversion sections PD of respective pixels is transferred to the accumulated charge detecting circuit 82. The accumulated charge detecting circuit 82 converts the amount of signal charge detected into a potential. The potential is applied by output wiring to the second electrode 68 via the amplifying circuit 83.

The imaging device 80 according to the present embodiment is configured such that the potential based on the amount of signal charge transferred from the photoelectric conversion sections PD of all pixels to the accumulated charge detecting circuit 82 is output from the accumulated charge detecting circuit 82 to the second electrode 68. In addition, a voltage retaining capacitance C having one terminal grounded is connected between the amplifying circuit 83 and the second electrode 68. A first electrode 67 is grounded.

With such a constitution, in the imaging device 80 according to the present embodiment, the potential based on the amount of signal charge generated and accumulated in the photoelectric conversion sections PD is supplied to the second electrode 68 of the shutter device 73. The transmittance of the first electrode 67 and the second electrode 68 of the shutter device 73 is adjusted according to the supplied potential. For example, when intense light is made incident, the transmittance of light by the first electrode 67 and the second electrode 68 of the shutter device 73 is decreased on the basis of the signal output. Thereby a dynamic range is extended.

In addition, as in the fourth embodiment, the imaging device 80 according to the present embodiment can extend the dynamic range also by a method of voltage application of signal processing using fast reaction (GHz) or the like.

The imaging device 80 according to the present embodiment can change transmittance in each pixel. Therefore, transmittance measurement is performed at a time of an imaging inspection or the like, and if output signals of respective pixels differ from an existing transmittance measurement result, variations from the measured transmittance can be corrected for each pixel by application voltage. A transmittance calibration method in a case where the transmittance of light by the nano-carbon laminated film 69 is set for each pixel will be described in the following.

### [Pixel Calibration Method]

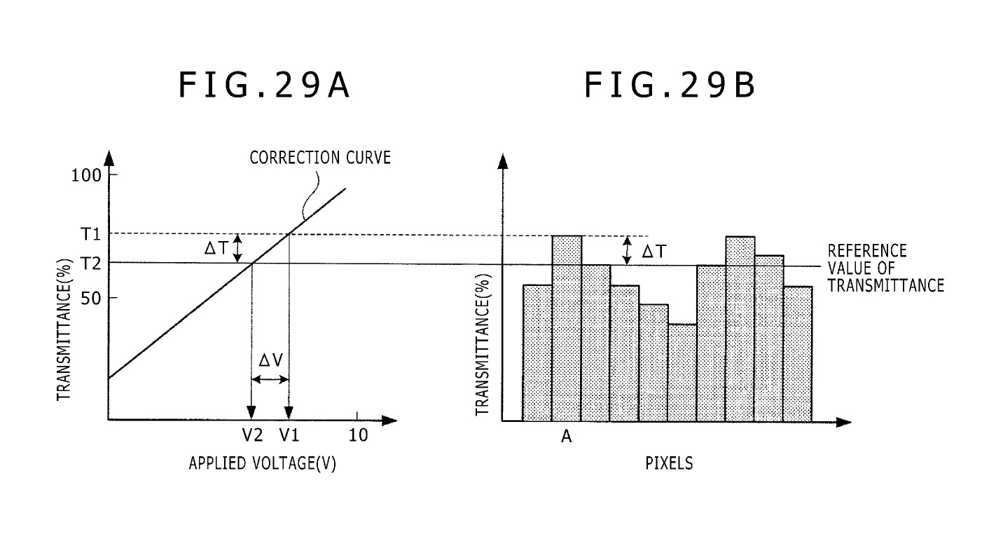

FIG. 29A is a diagram showing change in the transmittance of light by a graphene laminated film when application voltage is changed at a time of an imaging inspection. FIG. 29B shows transmittances predicted from actual output signals (or actually measured transmittances of respective pixels).

For example, as shown in FIG. 29A, the transmittance of light when a voltage V2 is applied to the nano-carbon laminated film 69 used in the present embodiment at a time of an imaging inspection is T2. As shown in FIG. 29B, the transmittance of light when the voltage V2 is applied to a region corresponding to a pixel A in the nano-carbon laminated film 69 is T1. In this case, it is shown that the transmittance T2 being set as a reference value, a variation of ΔT (T1−T2) occurs in the pixel A with respect to the transmittance T2.

In the pixel A, to change the transmittance T1 to the transmittance T2 as the reference at the time of the imaging inspection, correction is made by controlling the voltage. As shown in FIG. 29A, the application voltage at the time of the transmittance T1 of light is V1, and the application voltage at the time of the transmittance T2 of light is V2. Hence, when the transmittance T1 is corrected to the transmittance T2, the target transmittance T2 can be achieved by correcting the application voltage in the pixel A by a difference ΔV between the voltages V2 and V1. Amounts of shift in the transmittance of other pixels with respect to the transmittance T2 as the reference can be similarly corrected.

The method of calibrating the transmittance of light at each pixel position as described in the present embodiment can be realized in for example a device in which wiring for voltage application and pad sections are provided to a nano-carbon laminated film so that application voltage can be adjusted for each pixel and a device having a charge accumulating circuit provided for each pixel. In addition, the calibration method in the present embodiment is not limited to variations in the transmittance of light in each pixel. Also in a case where the film thickness of nano-carbon laminated films differs between wafers or between lots, provision can be made by changing application voltage to achieve a desired transmittance of light.

The imaging devices 75 and 80 according to the foregoing fifth and sixth embodiments have the shutter device 73 in close contact with the upper part of the solid-state imaging element 72, and can thus make accurate spatial selection of pixels as compared with the imaging device 65 according to the fourth embodiment. Therefore the transmittance of light and the wavelength region of transmissible light in each pixel of the effective pixel region can be adjusted accurately. Further, a reduction in height can be achieved, and thereby the devices can be miniaturized. In addition, similar effects to those of the fourth embodiment can be obtained.

In addition, the shutter device 73 according to the present embodiment is formed with graphene used for the electrodes, and thereby optical transparency is improved as compared with a case where indium tin oxide (ITO) is used for the electrodes.

The imaging devices 75 and 80 according to the present embodiments use a device having Si-base photoelectric conversion sections PD as sensor parts, but are not limited to the Si-base device. For example, provisions can be made variously for organic photoelectric conversion films as photoelectric conversion sections PD, bolometer type devices, and the like.

The shutter device 73 according to the fourth to sixth embodiments includes the nano-carbon laminated film 69 having the first electrode 67, the dielectric layer 71, and the second electrode 68 and the voltage power supply V serving as a voltage applying section. However, the shutter device 73 usable in the present embodiment is not limited to this. For example, the dielectric layer 71 may be formed of a normal dielectric constant material or a high dielectric constant material as in the nano-carbon laminated film shown in FIG. 10. Further, the nano-carbon laminated film 69 may have a constitution in which graphene doped with an impurity is provided as the first electrode and the second electrode as in the nano-carbon laminated film shown in FIG. 15. In addition, the nano-carbon laminated film 69 may have a constitution in which nano-carbon layers forming first electrodes and second electrodes and dielectric layers are alternately laminated as in the nano-carbon laminated film shown in FIG. 16. In addition, the shutter device 73 may have a constitution in which a voltage power supply V is connected via wiring to a nano-carbon laminated film having a structure obtained by laminating a plurality of nano-carbon layers.

### 7. Seventh Embodiment

### Electronic Apparatus

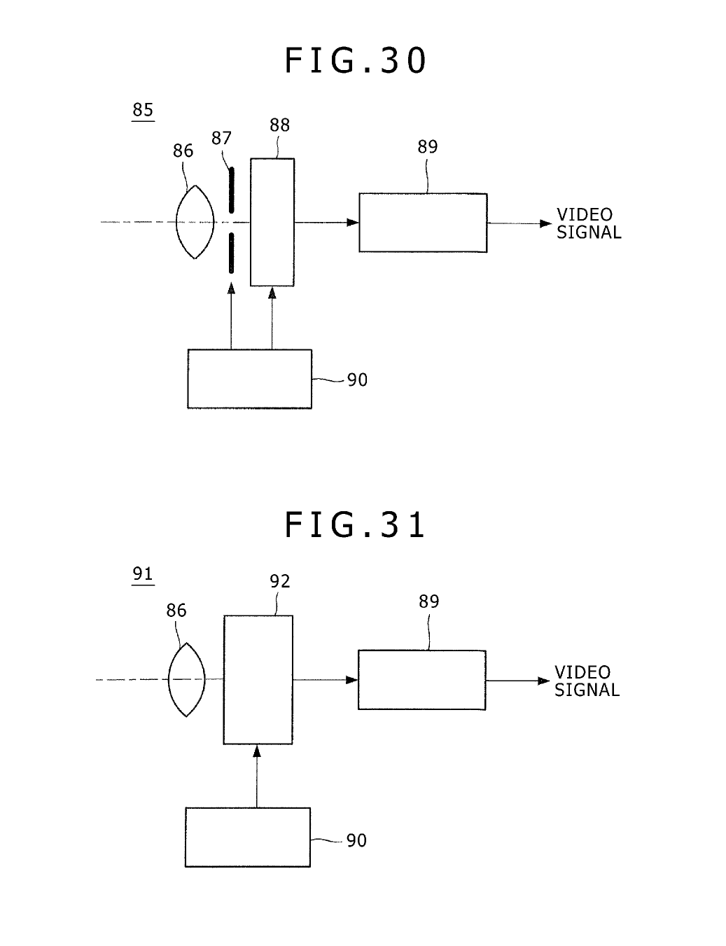

Description will next be made of an electronic apparatus according to a seventh embodiment of the present disclosure. FIG. 30 is a schematic block diagram of the electronic apparatus 85 according to the present embodiment. The electronic apparatus 85 according to the present embodiment includes a solid-state imaging element 88, an optical lens 86, a mechanical shutter 87, a driving circuit 90, and a signal processing circuit 89. The electronic apparatus 85 according to the present embodiment represents an embodiment in which the solid-state imaging element 11 in the foregoing first embodiment of the present disclosure is used as the solid-state imaging element 88 in the electronic apparatus (camera).

The optical lens 86 forms an image of image light (incident light) from a subject on an imaging surface of the solid-state imaging element 88. A corresponding signal charge is thereby accumulated within the solid-state imaging element 88 for a certain period. The mechanical shutter 87 controls a period of irradiation of the solid-state imaging element 88 with light and a period of shielding of the solid-state imaging element 88 from light. The driving circuit 90 supplies a driving signal for controlling transfer operation of the solid-state imaging element 88. The signal transfer of the solid-state imaging element 88 is performed according to the driving signal (timing signal) supplied from the driving circuit 90. The signal processing circuit 89 performs various kinds of signal processing. A video signal resulting from the signal processing is recorded on a recording medium such as a memory or the like, or output to a monitor.

The electronic apparatus 85 according to the present embodiment improves image quality because the solid-state imaging element 88 extends a dynamic range. In addition, because the solid-state imaging element 88 has a noise cancelling function, a noise signal component occurring due to a dark current can be removed.

The electronic apparatus 85 to which the solid-state imaging element 88 can be applied is not limited to cameras, but the solid-state imaging element 88 is also applicable to imaging devices such as digital cameras, camera modules for mobile devices including portable telephones, and the like.

In the present embodiment, the solid-state imaging element 11 in the first embodiment is used as the solid-state imaging element 88 in the electronic apparatus. However, the solid-state imaging elements 41, 61, and 101 manufactured in the first modification and the second and third embodiments can also be used as the solid-state imaging element 88.

The shutter device having the nano-carbon laminated film and the imaging device incorporating the shutter device in the foregoing fourth to sixth embodiments can also be used as parts of an electronic apparatus. An example thereof will be shown in the following.

### 8. Eighth Embodiment

### Electronic Apparatus

Description will next be made of an electronic apparatus 91 according to an eighth embodiment of the present disclosure. FIG. 31 is a schematic block diagram of the electronic apparatus 91 according to the example of the present embodiment. The electronic apparatus 91 according to the present embodiment is an example in which the mechanical shutter and the solid-state imaging element shown in FIG. 30 are replaced with an imaging device 92 provided with a shutter device. Specifically, the electronic apparatus 91 according to the present embodiment includes the imaging device 92, an optical lens 86, a driving circuit 90, and a signal processing circuit 89. Incidentally, the imaging device 92 represents an embodiment in which the imaging device 65 in the fourth embodiment of the present disclosure is used. In FIG. 31, parts corresponding to those of FIG. 30 are identified by the same reference numerals, and repeated description thereof will be omitted.

In the electronic apparatus 91 according to the present embodiment, the imaging device 92 provided with the shutter device is formed between the optical lens 86 and the signal processing circuit 89. The imaging device 92 includes the shutter device having a nano-carbon laminated film 69 forming a first electrode and a second electrode and a solid-state imaging element.

Also in the present embodiment, the first electrode and the second electrode in the shutter device of the imaging device 92 are formed by nano-carbon layers, and materials similar to those of the fourth embodiment can be used. The imaging device 92 is configured to be supplied with a desired potential on the basis of a signal from the driving circuit 90. The potential is applied to the first electrode and the second electrode in the shutter device of the imaging device 92. Thereby a dynamic range is extended, so that image quality is improved.

In the present embodiment, the imaging device 65 in the fourth embodiment is used as the imaging device 92 in the electronic apparatus. However, the imaging devices according to the fifth and sixth embodiments can also be used as the imaging device 92 in the electronic apparatus. While embodiments of the present disclosure have been shown above as the first to eighth embodiments, the present disclosure is not limited to the foregoing examples, but various changes can be made without departing from the spirit of the present disclosure. In addition, the constitutions according to the first to eighth embodiments can be combined with each other.

Incidentally, the present disclosure can also adopt the following constitutions.

(1) A solid-state imaging element including:
a plurality of pixels including a photoelectric conversion section; and
a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film.
(2) The solid-state imaging element according to (1),
wherein the nano-carbon laminated film is disposed in a position corresponding to a predetermined pixel.
(3) The solid-state imaging element according to (1) or (2),
wherein the nano-carbon laminated film is disposed in a position corresponding to an infrared pixel for obtaining
a near-infrared signal component, and
a signal amount in the infrared pixel is subtracted from
a signal amount in a visible light pixel for obtaining a visible light signal component, whereby the signal amount of the visible light pixel is corrected.
(4) The solid-state imaging element according to any one of (1) to (3),
wherein the nano-carbon layers are graphene.
(5) The solid-state imaging element according to any one of (1) to (4),
wherein the nano-carbon laminated film includes a first electrode formed by a single nano-carbon layer or a plurality of nano-carbon layers, a second electrode formed by a single nano-carbon layer or a plurality of nano-carbon layers, and a dielectric layer sandwiched between the first electrode and the second electrode.
(6) The solid-state imaging element according to (5),
wherein the dielectric layer is formed of a high dielectric constant material.
(7) The solid-state imaging element according to (5) or (6),
wherein the single nano-carbon layer or the plurality of nano-carbon layers forming the first electrode are doped with an impurity of a first conductivity type, and
the single nano-carbon layer or the plurality of nano-carbon layers forming the second electrode are doped with an impurity of a second conductivity type.
(8) The solid-state imaging element according to any one of (1) to (7),
wherein one blue pixel, one green pixel, and two red pixels arranged in regions adjacent to each other form a unit pixel, and
the nano-carbon laminated film is disposed in a position corresponding to one of the two red pixels in the unit pixel.
(9) The solid-state imaging element according to (8), wherein color correction is made using a signal component obtained in the red pixel provided with the nano-carbon laminated film.
(10) The solid-state imaging element according to any one of (1) to (7),
wherein one blue pixel, two green pixels, and one red pixel arranged in regions adjacent to each other form a unit pixel, and
the nano-carbon laminated film is disposed in a position corresponding to one of the two green pixels in the unit pixel.
(11) The solid-state imaging element according to any one of (1) to (7),
wherein four pixels, that is, a blue pixel, a green pixel, a red pixel, and a white pixel arranged in regions adjacent to each other form a unit pixel, and the nano-carbon laminated film is disposed in a position corresponding to the white pixel in the unit pixel.
(12) A calibration method of a solid-state imaging element, the solid-state imaging element including a plurality of pixels including a photoelectric conversion section, and a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film, the calibration method including:
adjusting transmittance in a position corresponding to each pixel of the nano-carbon laminated film for each pixel.
(13) An electronic apparatus including:
a solid-state imaging element including a plurality of pixels including a photoelectric conversion section;
a solid-state imaging element including a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film; and
   a signal processing circuit for processing an output signal output from the solid-state imaging element.
   (14) A shutter device including:
   a nano-carbon laminated film formed with a plurality of nano-carbon layers, transmittance of light and a wavelength region of transmissible light changing in the nano-carbon laminated film according to a voltage applied to the nano-carbon laminated film; and
   a voltage applying section applying the voltage to the nano-carbon laminated film.
   (15) The shutter device according to (14),
   wherein the nano-carbon layers are formed of graphene, and the nano-carbon laminated film includes a first electrode formed by a single layer of graphene or a plurality of layers of graphene, a second electrode formed by a single layer of graphene or a plurality of layers of graphene, and a dielectric layer sandwiched between the first electrode and the second electrode.
   (16) The shutter device according to (15),
   wherein the dielectric layer is formed of a high dielectric constant material.
   (17) The shutter device according to (15) or (16),
   wherein the single layer of graphene or the plurality of layers of graphene forming the first electrode are doped with an impurity of a first conductivity type, and

the single layer of graphene or the plurality of layers of graphene forming the second electrode are doped with an impurity of a second conductivity type.

(18) The shutter device according to any one of (14) to (17),
wherein the voltage applying section selectively applies the voltage to a predetermined region of the nano-carbon laminated film.
(19) An electronic apparatus including:
a solid-state imaging element including a photoelectric conversion section;
a shutter device including a nano-carbon laminated film disposed on a side of a light receiving surface of the solid-state imaging element and formed with a plurality of nano-carbon layers, transmittance of light and a wavelength region of transmissible light changing in the nano-carbon laminated film according to a voltage applied to the nano-carbon laminated film, and a voltage applying section applying the voltage to the nano-carbon laminated film; and
a signal processing circuit for processing an output signal output from the solid-state imaging element.
(20) The electronic apparatus according to (19),

wherein the voltage applying section is configured so as to be able to selectively apply the voltage to a predetermined region of the nano-carbon laminated film, and

transmittance of the shutter device is adjusted for each pixel of the solid-state imaging element.

The present disclosure contains subject matter related to that disclosed in Japanese Priority Patent Application JP 2012-134861 filed in the Japan Patent Office on Jun. 14, 2012, the entire content of which is hereby incorporated by reference.

What is claimed is:

1. A solid-state imaging element comprising:
a plurality of pixels including a photoelectric conversion section; and
a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film.

2. The solid-state imaging element according to claim 1, wherein the nano-carbon laminated film is disposed in a position corresponding to a predetermined pixel.

3. The solid-state imaging element according to claim 1, wherein the nano-carbon laminated film is disposed in a position corresponding to an infrared pixel for obtaining
a near-infrared signal component, and
a signal amount in the infrared pixel is subtracted from
a signal amount in a visible light pixel for obtaining a visible light signal component, whereby the signal amount of the visible light pixel is corrected.

4. The solid-state imaging element according to claim 1, wherein the nano-carbon layers are graphene.

5. The solid-state imaging element according to claim 1, wherein the nano-carbon laminated film includes a first electrode formed by a single nano-carbon layer or a plurality of nano-carbon layers, a second electrode formed by a single nano-carbon layer or a plurality of nano-carbon layers, and a dielectric layer sandwiched between the first electrode and the second electrode.

6. The solid-state imaging element according to claim 5, wherein the dielectric layer is formed of a high dielectric constant material.

7. The solid-state imaging element according to claim 5, wherein the single nano-carbon layer or the plurality of nano-carbon layers forming the first electrode are doped with an impurity of a first conductivity type, and the single nano-carbon layer or the plurality of nano-carbon layers forming the second electrode are doped with an impurity of a second conductivity type.

8. The solid-state imaging element according to claim 1, wherein one blue pixel, one green pixel, and two red pixels arranged in regions adjacent to each other form a unit pixel, and
the nano-carbon laminated film is disposed in a position corresponding to one of the two red pixels in the unit pixel.

9. The solid-state imaging element according to claim 8, wherein color correction is made using a signal component obtained in the red pixel provided with the nano-carbon laminated film.

10. The solid-state imaging element according to claim 1, wherein one blue pixel, two green pixels, and one red pixel arranged in regions adjacent to each other form a unit pixel, and
the nano-carbon laminated film is disposed in a position corresponding to one of the two green pixels in the unit pixel.

11. The solid-state imaging element according to claim 1, wherein four pixels, that is, a blue pixel, a green pixel, a red pixel, and a white pixel arranged in regions adjacent to each other form a unit pixel, and
the nano-carbon laminated film is disposed in a position corresponding to the white pixel in the unit pixel.

12. A calibration method of a solid-state imaging element, the solid-state imaging element including a plurality of pixels including a photoelectric conversion section, and a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film, the calibration method comprising:
adjusting transmittance in a position corresponding to each pixel of the nano-carbon laminated film for each pixel.

13. An electronic apparatus comprising:
a solid-state imaging element including a plurality of pixels including a photoelectric conversion section;
a solid-state imaging element including a nano-carbon laminated film disposed on a side of a light receiving surface of the photoelectric conversion section and formed with a plurality of nano-carbon layers, transmittance of light and a wavelength region of transmissible light changing in the nano-carbon laminated film according to a voltage applied to the nano-carbon laminated film; and
a signal processing circuit for processing an output signal output from the solid-state imaging element.

14. A shutter device comprising:
a nano-carbon laminated film formed with a plurality of nano-carbon layers, transmittance of light and a wavelength region of transmissible light changing in the nano-carbon laminated film according to a voltage applied to the nano-carbon laminated film; and
a voltage applying section applying the voltage to the nano-carbon laminated film.

15. The shutter device according to claim 14, wherein the nano-carbon layers are formed of graphene, and the nano-carbon laminated film includes a first electrode formed by a single layer of graphene or a plurality of layers of graphene, a second electrode formed by a single layer of graphene or a plurality of layers of graphene, and a dielectric layer sandwiched between the first electrode and the second electrode.

16. The shutter device according to claim 15, wherein the dielectric layer is formed of a high dielectric constant material.

17. The shutter device according to claim 15, wherein the single layer of graphene or the plurality of layers of graphene forming the first electrode are doped with an impurity of a first conductivity type, and the single layer of graphene or the plurality of layers of graphene forming the second electrode are doped with an impurity of a second conductivity type.

18. The shutter device according to claim 14, wherein the voltage applying section selectively applies the voltage to a predetermined region of the nano-carbon laminated film.

19. An electronic apparatus comprising:
a solid-state imaging element including a photoelectric conversion section;
a shutter device including a nano-carbon laminated film disposed on a side of a light receiving surface of the solid-state imaging element and formed with a plurality of nano-carbon layers, transmittance of light and a wavelength region of transmissible light changing in the nano-carbon laminated film according to a voltage applied to the nano-carbon laminated film, and a voltage applying section applying the voltage to the nano-carbon laminated film; and
a signal processing circuit for processing an output signal output from the solid-state imaging element.

20. The electronic apparatus according to claim 19, wherein the voltage applying section is configured so as to be able to selectively apply the voltage to a predetermined region of the nano-carbon laminated film, and
transmittance of the shutter device is adjusted for each pixel of the solid-state imaging element.
